(19) United States
(12) Patent Application Publication
(10) Pub. No.: US 2012/0262793 A1
(43) Pub. Date: Oct. 18, 2012

(54) BLACK CURABLE COMPOSITION FOR WAFER - LEVEL LENS, AND WAFER - LEVEL LENS

(75) Inventors: Masaru Yoshikawa, Haibara-gun (JP); Yushi Kaneko, Haibara-gun (JP); Yoshiharu Yabuki, Haibara-gun (JP)

(73) Assignee: FUJIFILM CORPORATION, Minato-ku, Tokyo (JP)

(21) Appl. No.: 13/518,696

(22) PCT Filed: Jan. 20, 2011
(86) PCT No.: PCT/JP2011/051537

§ 371 Date: Jun. 22, 2012

(30) Foreign Application Priority Data
Jan. 20, 2010 (JP) 2010-9760

(51) Int. Cl. G03F 7/004; G03F 7/027; G03F 7/20; G02B 7/02

(52) U.S. Cl. 359/601; 430/286.1; 430/285.1; 430/325

(57) ABSTRACT

A black curable composition for a wafer-level lens including (A) a metal-containing inorganic pigment, (B) a polymerization initiator, (C) a polymerizable compound, and (D) a cardo resin.

### TECHNICAL FIELD

The present invention relates to a black curable composition for a wafer-level lens, which is useful for forming a light-shielding layer of a wafer-level lens having plural lenses arranged on the substrate, and a wafer-level lens having a light-shielding film obtained by using the same.

### RELATED ART

Mobile terminals of recent electronic device, such as mobile phones or personal digital assistants (PDAs), have small and thin image pickup units. Generally, such an image pickup unit includes a solid-state image pickup element, such as a Charge Coupled Device (CCD) image sensor or a Complementary Metal-Oxide Semiconductor (CMOS) image sensor, and a lens that molds subject images on the solid-state image pickup element.

With miniaturization and thickness reduction of portable terminals and propagation of portable terminals, further miniaturization and thickness reduction of image pickup units to be mounted thereon are requested, together with provision of adequate productivity. To cope with such a request, a mass-production method of an image pickup unit is known whereby a lens substrate having plural lenses formed thereon and a sensor substrate having plural solid-state image pickup devices formed thereon are integrally combined, and the lens substrate and the sensor substrate are cut in such a manner that each of the cut substrates includes a lenses and solid-state image pickup devices. Other production methods include, for example: a method of fabricating an image pickup unit whereby only lenses are formed on a glass wafer, the glass wafer is cut to have a size suitable for combined use with an individual sensor substrate piece, and combined with an individual image pickup substrate piece that has been cut to have an appropriate size in advance; a method whereby plural lenses are formed in a mold by using only a resin, the lenses are combined with a sensor substrate, and cutting the resultant, and a method of fabricating an image pickup unit whereby a lens substrate is cut to have an size appropriate for combination with an individual sensor substrate piece, and is combined with an image pickup substrate piece that has been cut to have an appropriate size in advance.

A conventional wafer-level lens array is known which is obtained by dripping a curable resin material on a surface of a flat plate substrate formed from a light-transmissive material such as glass, shaping the resin material into a given shape in a mold, and curing the resin material in this state to form plural lenses (for example, see Japanese Patent No. 3,926,380 and International Publication No. WO 2008/102648). In some cases, a light-shielding region made of a black film, a metal film, or the like is formed at a region other than the lens region of the wafer-level lens, or at a portion of the lens, in order to control an amount of light. The light-shielding region is generally formed by applying a curable light-shielding composition or depositing a metal.

Another wafer-level lens array is known which is obtained by forming plural holes through a silicon substrate, separately-prepared spherical lens material is disposed at each through hole, fusing the lens material to the substrate by soldering, and polishing the lens material to form plural lenses (see U.S. Pat. No. 6,426,829). The lens obtained by this method may be provided with a light-shielding region formed by a black film, a metal film, or the like similar to the above, in order to control an amount of light.

Formation of a light-shielding region by deposition of a metal has problems in that the process is complex, the lens bends after deposition, and light scattering occurs due to reflection by the metal light-shielding film, and further improvements are requested from the viewpoint of both productivity and performance.

In some cases, a carbon black-containing photosensitive resin composition (light-shielding composition) for use in, for example, black matrices of LCDs is coated to form a light-shielding region.

### SUMMARY OF INVENTION

The present invention has been made in view of the problems described above, and an object of the present invention is provision of a black curable composition for a wafer-level lens that is capable of forming a cured film having excellent light-shielding properties and that has excellent curing sensitivity when forming a pattern.

In addition, another object of the present invention is provision of a wafer-level lens which can be produced easily and with which the light amount can be appropriately adjusted by the presence of a light-shielding film formed using the black curable composition of the present invention.

As a result of thorough studies, the inventors of the present invention have found that the above objects can be addressed by providing a black curable composition capable of forming a light-shielding film having excellent transmittance in the ultraviolet region and excellent light-shielding properties in a wavelength range ranging from the visible light region to the infrared region, and having an increased hardness. Based on the finding, the present inventors have made the present invention.

Aspects of the present invention include the following:

<1>. A black curable composition for a wafer-level lens comprising (A) a metal-containing inorganic pigment, (B) a polymerization initiator, (C) a polymerizable compound, and (D) a cardo resin.

<2>. The black curable composition for a wafer-level lens according to <1>, wherein the (A) metal-containing inorganic pigment comprises titanium black.

<3>. The black curable composition for a wafer-level lens according to <1> or <2>, wherein the (D) cardo resin is a resin selected from the group consisting of an epoxy resin, a polyester resin, a polycarbonate resin, an acrylic resin, a polyether resin, a polyamide resin, a polyurea resin, and a polyimide resin, and wherein the (D) cardo resin has a fluorene skeleton.

<4>. The black curable composition for a wafer-level lens according to <3>, wherein the fluorene skeleton included in the (D) cardo resin has the following structure:

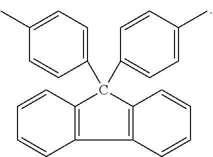

<5>. The black curable composition for a wafer-level lens according to any one of <1> to <4>, wherein the (D) cardo resin comprises a constituent unit derived from a compound that contains a thiol group.

<6>. The black curable composition for a wafer-level lens according to any one of <1> to <5>, wherein the proportion of cardo structures in the (D) cardo resin is from 30% by mass to 90% by mass relative to the total mass of the cardo resin.

<7>. The black curable composition for a wafer-level lens according to any one of <1> to <6>, wherein the (D) cardo resin consists of at least one type of cardo-structure-containing repeating unit.

<8>. The black curable composition for a wafer-level lens according to any one of <1> to <6>, wherein the (D) cardo resin includes at least one type of cardo-structure-containing repeating unit and at least one type of repeating unit that does not contain a cardo structure.

<9>. The black curable composition for a wafer-level lens according to any one of <1> to <8>, wherein the molecular weight of the (D) cardo resin is from 3,000 to 20,000.

<10>. The black curable composition for a wafer-level lens according to any one of <1> to <9>, wherein the (B) polymerization initiator comprises an oxime initiator.

<11>. The black curable composition for a wafer-level lens according to <10>, wherein the (B) polymerization initiator is selected from the group consisting of the following compounds (I-1) to (I-27):

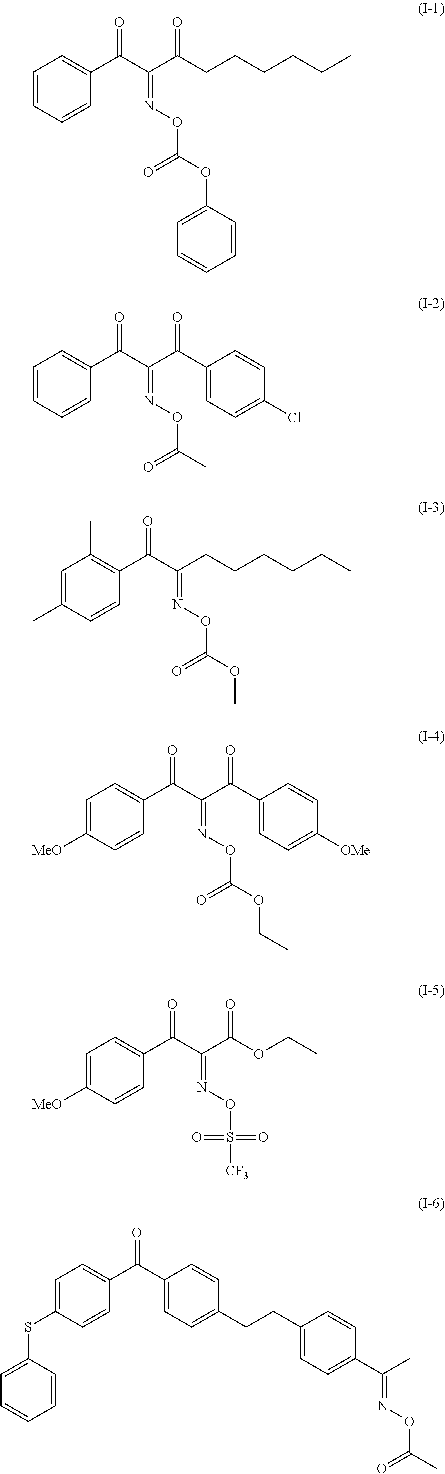

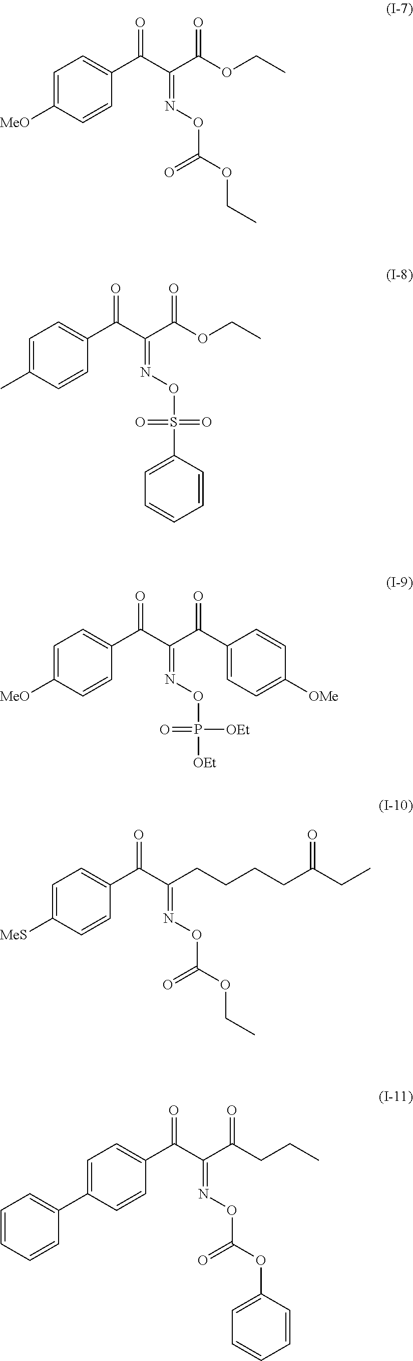

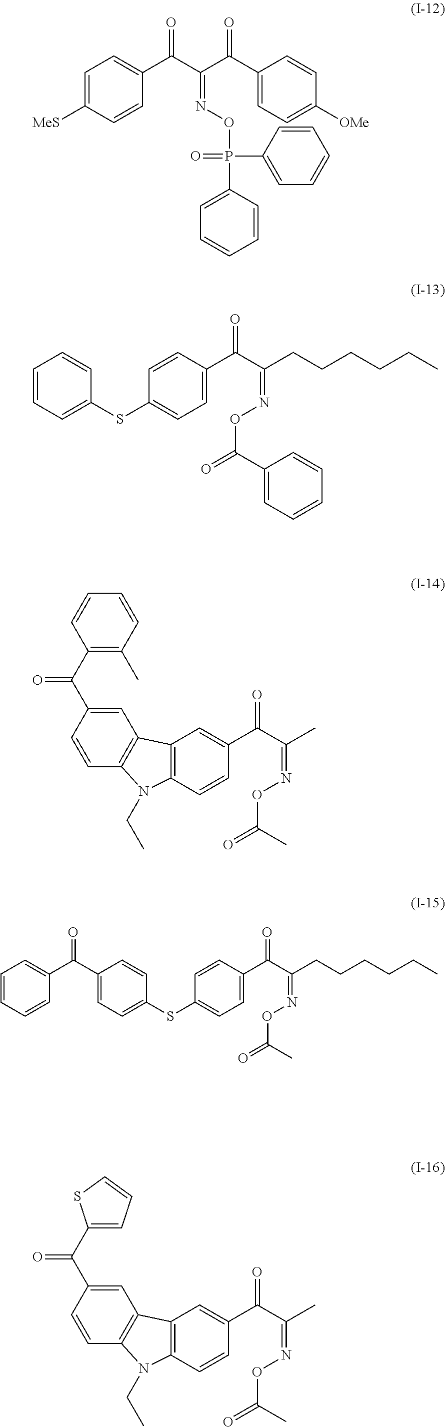

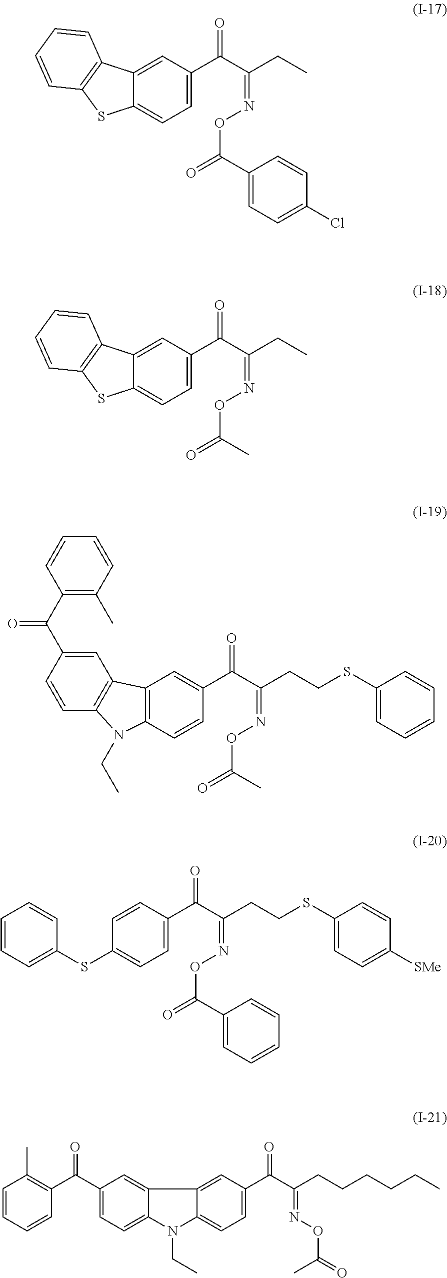

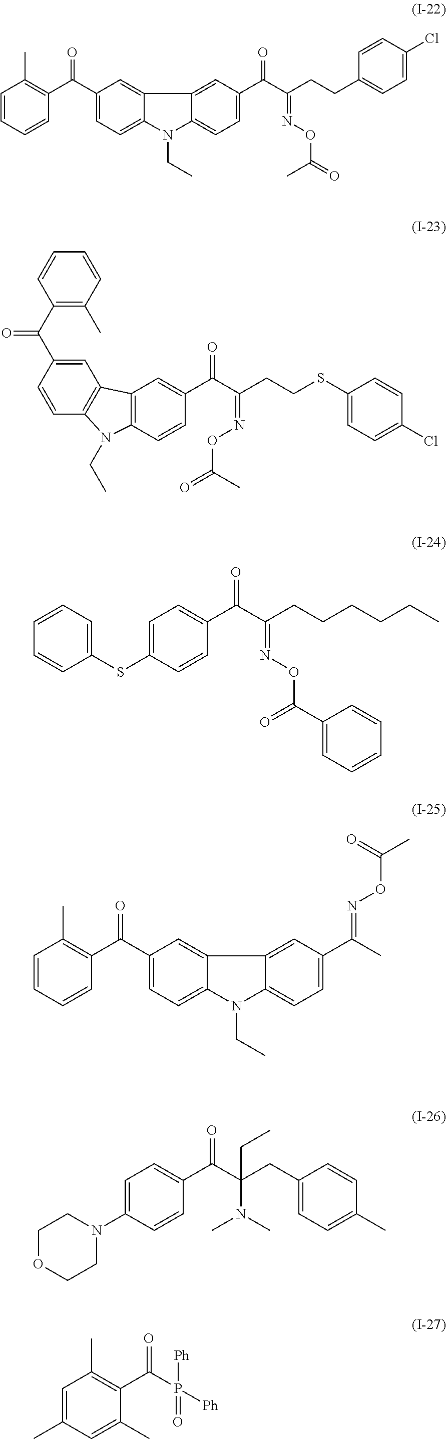

<12>. The black curable composition for a wafer-level lens according to any one of <1> to <11>, wherein the (C) polymerizable compound comprises at least one of pentaerythritol triacrylate or dipentaerythritol hexaacrylate.

<13>. The black curable composition for a wafer-level lens according to any one of <1> to <12>, further comprising (E) an organic pigment.

<14>. The black curable composition for a wafer-level lens according to any one of <1> to <13>, further comprising a pigment dispersant that includes a polyester-containing side chain and a side chain having a carboxylic acid group, a sulfonic acid group, or a phosphoric acid group.

<15>. A wafer-level lens comprising a substrate, a lens provided on the substrate, and a light-shielding film provided at a peripheral region of the lens, wherein the light-shielding film is formed using the black curable composition for a wafer-level lens of any one of <1> to <14>.

<16>. A method of forming a light-shielding pattern including:

forming a black curable layer containing the black curable composition for a wafer level lens of any one of <1> to <14> on a substrate on which plural lenses are provided; and

patternwise exposing the black curable layer to light and developing the black curable layer, thereby forming, at peripheral regions of the plural lenses, light-shielding portions containing a cured product of the black curable composition for a wafer level lens.

According to the present invention, a black curable composition for a wafer-level lens that is capable of forming a cured film having excellent light-shielding properties and that has excellent curing sensitivity when forming a pattern, can be provided.

Further, a wafer-level lens which can be produced easily and with which the light amount can be appropriately adjusted by the presence of a light-shielding film, can be provided by using the black curable composition of the present invention.

### BRIEF DESCRIPTION OF DRAWINGS

FIG. 1 is a plan view showing an example of the structure of a wafer-level lens.

FIG. 2 is a cross-sectional view of the structure of the wafer-level lens shown in FIG. 1, taken along the line A-A.

FIG. 3 is a view showing a state in which a material for forming a lens is being supplied onto a substrate.

FIGS. 4A to 4C are views showing the order in which lenses are shaped on a substrate by using a mold.

FIGS. 5A to 5C are schematic views showing a process of forming a patterned light-shielding film on a substrate on which lenses have been formed and shaped.

FIG. 6 is a view showing another example of the wafer-level lens structure.

FIGS. 7A to 7C are schematic views showing another example of a process of forming a light-shielding film.

FIGS. 8A to 8C are schematic views showing a process of forming a lens on a substrate having a patterned light-shielding film.

### DESCRIPTION OF EMBODIMENTS

In the below, the black curable composition for a wafer-level lens according to the present invention (hereinafter sometimes referred to as “black curable composition”) and the wafer-level lens having a light-shielding film formed using the black curable composition are described in detail.

### <Black Curable Composition>

The black curable composition for a wafer-level lens according to the present invention includes (A) a metal-containing inorganic pigment, (B) a polymerization initiator, (C) a polymerizable compound, and (D) a cardo resin. Individual components contained in the black curable composition for a wafer-level lens according to the invention are sequentially described below.

<(A) Metal-Containing Inorganic Pigment>

The (A) metal-containing inorganic pigment used in the invention is preferably a metal-containing pigment having absorbance over a region ranging from the visible light region to the infrared region, from the viewpoint of exerting light-shielding properties over the region ranging from the visible light region to the infrared region. Examples of the (A) metal-containing inorganic pigment include a pigment made of a simple metal, and a pigment made of a metal compound such as a metal oxide or a metal complex salt.

Specific examples thereof include zinc oxide, white lead, lithophone, titanium oxide, chromium oxide, iron oxide, precipitated barium sulfate, barite powder, red lead, red iron oxide, chrome yellow, zinc yellow (zinc yellow 1, zinc yellow 2), ultramarine blue, Prussian blue (potassium iron ferrocyanide), zircon gray, praseodymium yellow, chromium titanium yellow, chromium green, peacock, Victoria green, ferric hexacyanoferrate (unrelated to Prussian blue), vanadium zirconium blue, chromium tin pink, manganese pink, and salmon pink. In addition, examples of black metal-containing inorganic pigments include a metal oxide containing one type of metal element, or two or more types of metal element, selected from the group consisting of Co, Cr, Cu, Mn, Ru, Fe, Ni, Sn, Ti, and Ag, and metal nitrides containing one type of metal element, or two or more types of metal element, selected from the group consisting of Co, Cr, Cu, Mn, Ru, Fe, Ni, Sn, Ti, and Ag. These metal-containing pigments may be used singly, or in mixture of two or more thereof. Carbon black is not included in the scope of the metal-containing inorganic pigment according to the invention since carbon black does not contain a metal.

In particular, for the purpose of achieving light-shielding properties over a broad wavelength range of from ultraviolet region to infrared region, plural metal-containing pigments may be mixed and used instead of using a single metal-containing pigment.

The metal-containing inorganic pigment is preferably titanium black or a metal pigment of silver or tin, from the viewpoint of light-shielding properties and curability. The metal-containing inorganic pigment is most preferably titanium black from the viewpoint of achieving light-shielding properties over a range of from ultraviolet region to infrared region.

The term “titanium black” as used in the invention refers to black particles containing a titanium atom, and is preferably a lower titanium oxide, a titanium oxynitride, or the like. The titanium black particles may be surface-modified for the purpose of improving dispersibility, suppressing aggregability or the like, as necessary. Specifically, the titanium black may be coated with silicon oxide, titanium oxide, germanium oxide, aluminum oxide, magnesium oxide, or zirconium oxide. Treatment of the titanium black with a water-repellent substance as described in Japanese Patent Application Laid-Open (JP-A) No. 2007-302836 is also possible.

The titanium black may be contained in combination with one of, or two or more of, metal-containing black pigments such as a composite oxide containing at least one of Cu, Fe, Mn, V, Ni, or the like, cobalt oxide, iron oxide, carbon black, or aniline black, for the purpose of controlling, for example, dispersibility or coloring properties. In this case, the proportion of titanium black particles to the total amount of metal-containing inorganic pigments is preferably 50% by mass or higher.

Examples of commercially available products of titanium black include titanium black 10S, 12S, 13R, 13M, 13M-C, 13R and 13R-N (tradenames, manufactured by Mitsubishi Materials Corporation), and TILACK D (tradename, manufactured by Ako Kasei Co., Ltd.).

Examples of methods of producing titanium black include, but are not limited to, a method of heating and reducing a mixture of titanium dioxide and metallic titanium under a reducing atmosphere (JP-A No. 49-5432); a method of reducing, under a hydrogen-containing reducing atmosphere, ultrafine titanium dioxide obtained by high-temperature hydrolysis of titanium tetrachloride (JP-A No. 57-205322); a method of reducing titanium dioxide or titanium hydroxide at high temperatures in the presence of ammonia (JP-A No. 60-65069 and JP-A No. 61-201610); and a method of depositing a vanadium compound on titanium dioxide or titanium hydroxide, and reducing the resultant at high temperatures in the presence of ammonia (JP-A No. 61-201610).

The average primary particle size of the titanium black particles is not particularly limited, and is preferably from 3 nm to 2,000 nm, more preferably from 10 nm to 500 nm, and most preferably from 10 nm to 100 nm, from the viewpoint of dispersibility and coloring properties.

The specific surface area of the titanium black is not particularly limited, and the specific surface area of the titanium black as measured by a BET method is, in usual cases, preferably from about 5 to about 150 m²/g, and particularly preferably from about 20 to about 100 m²/g.

The (A) metal-containing inorganic pigment according to the invention, of which typical example is titanium black, has a average primary particle diameter of preferably from 5 nm to 0.01 mm. The average primary particle diameter of the (A) metal-containing inorganic pigment is more preferably in the range of from 10 nm to 1 μm from the viewpoint of dispersibility, light-shielding properties, and sedimentation properties over time.

The black curable composition according to the invention may include only a single metal-containing inorganic pigment, or include two or more metal-containing inorganic pigments in combination. As described below, at least one organic pigment and/or at least one dye may be additionally used if desired, for the purpose of, for example, controlling light shielding properties.

The content of metal-containing inorganic pigment in the black curable composition is preferably in the range of from 5 to 70% by mass, and more preferably from 10 to 50% by mass, relative to the total solids content of the black curable composition. Within the above range, the light-shielding properties are favorable, and developability when forming a pattern is also favorable.

In the invention, an expression “the total solids content of the black curable composition” refers to the total amount of the components of the black curable composition except organic solvent.

The incorporation of the (A) metal-containing inorganic pigment into the black curable composition is preferably conducted by first preparing a pigment dispersion in which the (A) metal-containing inorganic pigment is dispersed with a known pigment dispersant, and then incorporating the resultant pigment dispersion into the black curable composition, from the viewpoint of uniformity of the resultant black curable composition.

The pigment dispersant is preferably a high-molecular-weight compound having a heterocyclic ring in a side chain thereof. The high-molecular-weight compound is preferably a polymer containing a polymerization unit derived from a monomer represented by General Formula (1) described in JP-A No. 2008-266627, or a monomer of maleimide or a maleimide derivative. Pigment dispersants of these types are detailed in paragraph numbers [0020] to [0047] of JP-A No. 2008-266627, and the dispersants described therein are also applicable to the present invention.

Another example of the pigment dispersant is a compound that includes a polyester-containing side chain and a side chain having a carboxylic acid group, a sulfonic acid group, or a phosphoric acid group. The use of the pigment dispersant that includes a polyester-containing side chain and a side chain having a carboxylic acid group, a sulfonic acid group, or a phosphoric acid group improves dispersibility of the metal-containing inorganic pigment and the stability of the black curable composition over time, due to excellent adsorption properties of the pigment dispersant towards the metal-containing inorganic pigment.

Examples of the compound that includes a polyester-containing side chain and a side chain having a carboxylic acid group, a sulfonic acid group, or a phosphoric acid group are described in JP-A Nos. 2008-266627, 2010-70601, 2010-53182, 2010-106268, 2010-169863, and 2010-211200.

The pigment dispersant may be arbitrarily selected from known compounds besides those described above, and commercially available dispersants and surfactants may be used. Specific examples of commercially available products that can be used as dispersants include cationic surfactants such as organosiloxane polymer KP341 (tradename, manufactured by Shin-Etsu Chemical Co., Ltd.), (meth)acrylic (co)polymer POLYFLOW No. 75, No. 90, and No. 95 (tradename, all manufactured by KYOEISHA CHEMICAL Co., LTD), and W001 (tradename, available from Yusho Co., Ltd.); nonionic surfactants such as polyoxyethylene lauryl ether, polyoxyethylene stearyl ether, polyoxyethylene oleyl ether, polyoxyethylene octyl phenyl ether, polyoxyethylene nonyl phenyl ether, polyethyleneglycol dilaurate, polyethyleneglycol distearate, and sorbitan fatty acid esters; anionic surfactants such as W004, W005, and W017 (tradenames, all available from Yusho Co., Ltd.); polymer dispersants such as EFKA-46, EFKA-47, EFKA-47EA, EFKA POLYMER 100, EFKA POLYMER 400, EFKA POLYMER 401, and EFKA POLYMER 450 (tradenames, all manufactured by BASF Japan Ltd.) and DISPERSE AID 6, DISPERSE AID 8, DISPERSE AID 15, and DISPERSE AID 9100 (tradenames, all manufactured by San Nopco LTD.); various SOLSPERSE dispersants such as SOLSPERSE 3000, 5000, 9000, 12000, 13240, 13940, 17000, 24000, 26000, 28000, 32000, and 36,000 (tradenames, all manufactured by The Lubrizol Japan Corporation); and ADEKA PLURONIC L31, F38, L42, L44, L61, L64, F68, L72, P95, F77, P84, F87, P94, L101, P103, F108, L121, and P-123 (tradenames, all manufactured by ADEKA CORPORATION), ISONET S-20 (Sanyo Chemical Industries, Ltd.), DISPERBYK 101, 103, 106, 108, 109, 111, 112, 116, 130, 140, 142, 162, 163, 164, 166, 167, 170, 171, 174, 176, 180, 182, 2000, 2001, 2050, and 2150 (tradenames, all manufactured by BYK Chemie), and BYK-161 (tradename, manufactured by BYK Chemie).

Other preferable examples of the dispersant include oligomers or polymers having a polar group at a molecular terminal or at a side chain thereof, such as acrylic copolymers.

From the viewpoint of dispersibility, developability, and sedimentation properties, a resin having a polyester chain in a side chain and disclosed in JP-A No. 2010-106268 is preferable as a dispersant. In particular, a resin having a polyester chain in a side chain is preferable from the viewpoint of dispersibility. Further, a resin further having an acid group is preferable from the viewpoint of dispersibility and resolution. The acid group has a pKa value of preferably 6 or less, and is particularly preferably an acid group derived from carboxylic acid, sulfonic acid, or phosphoric acid, from the viewpoint of adsorption properties.

A resin having a polycaprolactone side chain (as a polyester chain), and also having a carboxylic acid group is most preferable from the viewpoint of solubility in the dispersion liquid, dispersing properties, and developability.

When a pigment dispersion is prepared, the content of pigment dispersant is preferably in the range of from 1% by mass to 90% by mass, and more preferably from 3% by mass to 70% by mass, relative to the total solids content of colorants (including metal-containing black pigments and other colorants) contained in the pigment dispersion.

<(B) Polymerization Initiator>

The black curable composition according to the invention contains (B) a polymerization initiator.

The polymerization initiator in the black curable composition according to the invention is a compound that is degraded by light or heat to initiate and promote the polymerization of the below-described (C) polymerizable compound. The polymerization initiator preferably has absorption in a wavelength range of from 300 nm to 500 nm.

Specifically, examples of the polymerization initiator include organic halogenated compounds, oxadiazole compounds, carbonyl compounds, ketal compounds, benzoin compounds, organic peroxide compounds, azo compounds, coumarin compounds, azide compounds, metallocene compounds, organic boric acid compounds, disulfonic acid compounds, oxime compounds, onium salt compounds, acyl phosphine (oxide) compounds, and hexaarylbiimidazole compounds. In particular, oxime ester compounds and hexaarylbiimidazole compounds are preferable from the viewpoints of residues and adhesion properties, and oxime ester compounds are particularly preferable.

The (B) polymerization initiator used in the black curable composition according to the invention is preferably an oxime compound serving as an oxime initiator from the viewpoints of sensitivity and dissolution properties. Examples of preferable oxime compounds include known compounds that are known as photopolymerization initiators for photosensitive compositions such as for applications in electronic parts. The oxime compound for use may be selected from, for example, the compounds described in JP-A No. 57-116047, JP-A No. 61-24558, JP-A No. 62-201859, JP-A No. 62-286961, JP-A No. 7-278214, JP-A No. 2000-80068, JP-A No. 2001-233842, JP-A No. 2004-534797, JP-A No. 2002-538241, JP-A No. 2004-359639, JP-A No. 2005-97141, JP-A No. 2005-220097, WO2005-080337A1, JP-A No. 2002-519732, JP-A No. 2001-235858, and JP-A No. 2005-227525.

In general, oxime compounds exhibit low sensitivity since absorption thereof in near-ultraviolet regions, for example at a wavelength of 365 nm or 405 nm, is small. However, it is known that the sensitivity of oxime compounds is improved by sensitizers through increase in sensitivity in near-ultraviolet regions. It is also known that the effective radical generation amount can be increased by combined use with a co-sensitizer, such as an amine or a thiol. However, higher sensitivity has been requested for practical applications.

In the invention, even an oxime compound having small absorption in near ultraviolet regions, such as at a wavelength of 365 nm or 405 nm, can be remarkably sensitized to have practically sensitivity through combined use with a sensitizer.

Oxime compounds that exhibit small absorption in a wavelength region of from 380 nm to 480 nm and that exhibit high decomposition efficiency are preferable. However, oxime compounds that exhibit large absorption in a wavelength region of from 380 nm to 480 nm are also preferable if the compounds are decomposed by light such that the absorption thereof in the wavelength region is decreased (the side products have absorption at a shorter wavelength).

Specific examples (Exemplary Compounds I-1 to I-27) of the polymerization initiator are shown below.

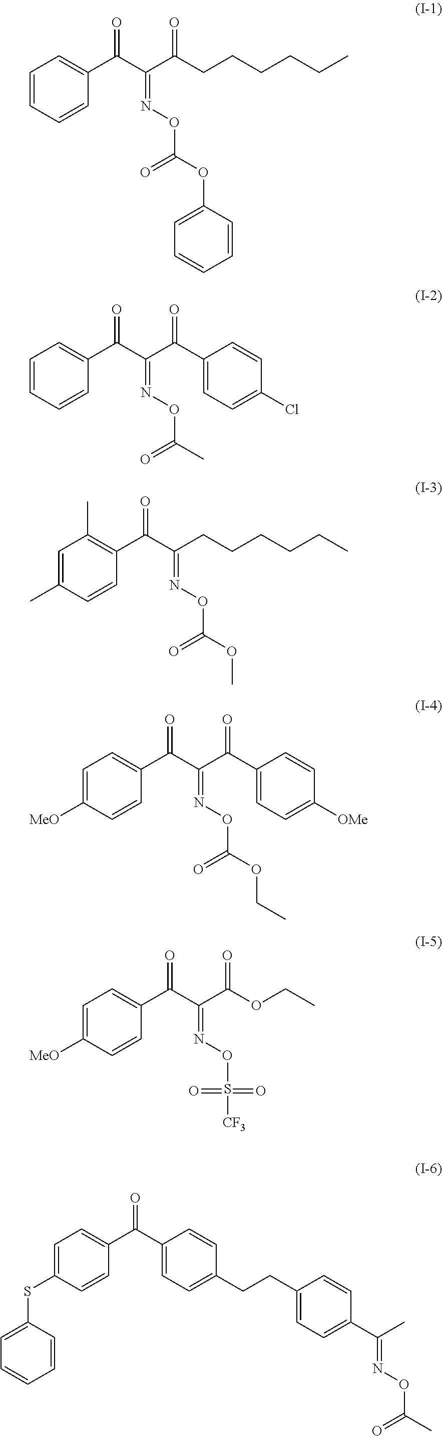

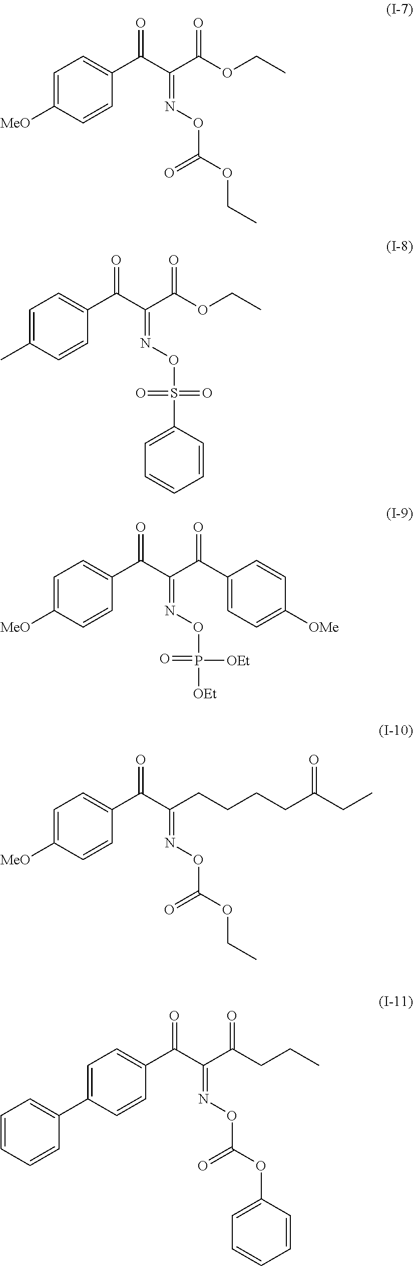

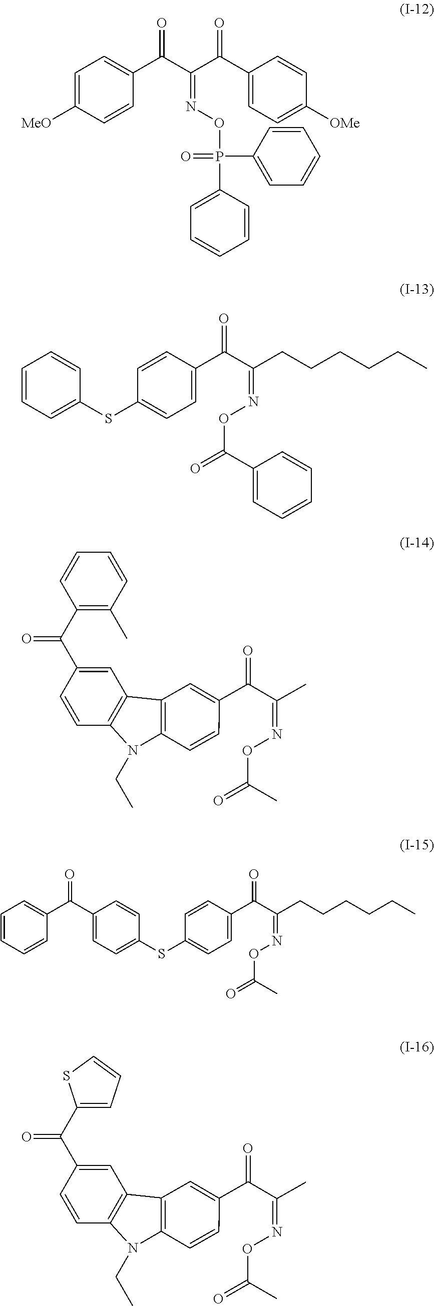

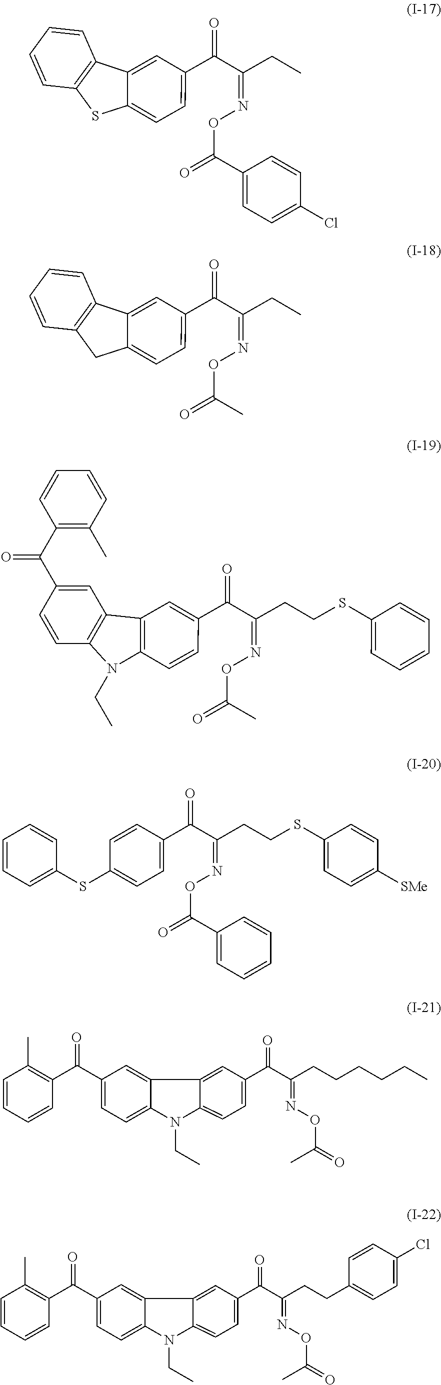

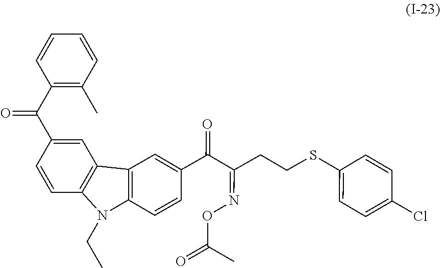

Polymerization initiator

| Compound No. | Structure |
|---|---|
| Compound I-24 | 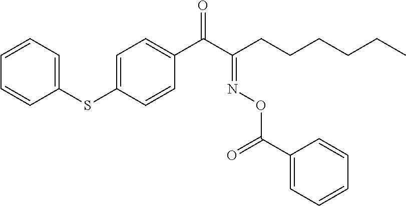 IRGACURE OXE01 (manufactured by BASF Japan Ltd.) |
| Compound I-25 | 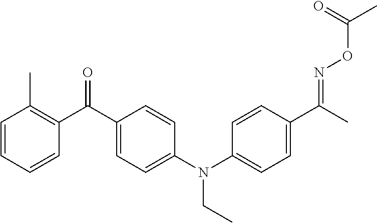 IRGACURE OXE02 (manufactured by BASF Japan Ltd.) |
| Compound I-26 | 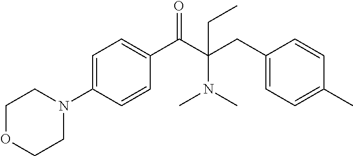 IRGACURE 379 (manufactured by BASF Japan Ltd.) |
| Compound I-27 | 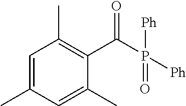 DAROCUR TPO (manufactured by BASF Japan Ltd.) |

Of these, compounds (I-1) to (I-25) are oxime compounds.

Examples of hexaarylbiimidazole compounds include various compounds described in JP-B No. 6-29285, U.S. Pat. No. 3,479,185, U.S. Pat. No. 4,311,783, and U.S. Pat. No. 4,622,286, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methyl phenyl)-4,4′,5,5′-tetraphenylbiimidazole, and 2,2′-bis(o-trifluorophenyl)-4,4′,5,5′-tetraphenyl biimidazole.

The polymerization initiator in the invention may be used singly, or in combination of two or more thereof.

In the black curable composition according to the invention, the content of polymerization initiator is preferably from 0.1% by mass to 30% by mass, more preferably from 1% by mass to 25% by mass, and particularly preferable from 2% by mass to 20% by mass, relative to the total solids content of the black curable composition.

<(C) Polymerizable Compound>

The black curable composition according to the invention includes a polymerizable compound.

The (C) polymerizable compound is preferably a compound having at least one addition-polymerizable ethylenic unsaturated group and having a boiling point of 100° C. or higher at normal pressure.

In the present specification, the expression (meth)acrylate is sometimes used to as a generic term for acrylate and methacrylate.

Examples of the compound having at least one addition-polymerizable ethylenic unsaturated group and having a boiling point of 100° C. or higher at a normal pressure include monofunctional acrylates and methacrylates such as polyethylene glycol mono(meth)acrylate, polypropylene glycol mono(meth)acrylate, and phenoxyethyl(meth)acrylate; and polyfunctional acrylates and methacrylates such as polyethylene glycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol hexa(meth)acrylate, hexanediol(meth)acrylate, trimethylolpropane tri(acryloyloxypropyl)ether, tri(acryloyloxyethyl)isocyanurate, compounds obtained by adding ethylene oxide and/or propylene oxide to a polyfunctional alcohol such as glycerin or trimethylolethane and thereafter (meth)acrylating the resultant product, poly(meth)acrylated products of pentaerythritol or dipentaerythritol, urethane acrylates described in Japanese Examined Patent Application Publication (JP-B) Nos. 48-41708 and 50-6034 and JP-A No. 51-37193, polyester acrylates described in JP-A No. 48-64183 and JP-B Nos. 49-43191 and 52-30490, and epoxy acrylates each of which is a reaction product of an epoxy resin and (meth)acrylic acid.

Further examples of polymerizable compounds that can be used include photocurable monomers and oligomers described in Journal of the Adhesive Society of Japan, Vol. 20, No. 7, p. 300-308.

Further, compounds of General Formulae (1) and (2) of JP-A No. 10-62986, which are described together with specific examples thereof and obtained by adding ethylene oxide and/or propylene oxide to polyfunctional alcohols (such as those described above) and (meth)acrylating the resultant, may be used as polymerizable compounds.

Among them, the polymerizable compound is preferably pentaerythritol triacrylate, dipentaerythritol penta(meth)acrylate, dipentaerythritol hexa(meth)acrylate, or a compound obtained by interposing at least one ethyleneglycol residue or propyleneglycol residue between the dipentaerythritol moiety and the (meth)acryloyl groups in dipentaerythritol hexa(meth)acrylate or dipentaerythritol penta(meth)acrylate. It is also possible to use, as the polymerizable compound, an oligomerized form of any of these compounds. A succinic acid-modified monomer of dipentaerythritol pentaacrylate is also preferable.

Also preferable are urethane acrylates such as those described in JP-B No. 48-41708, JP-A No. 51-37193, JP-B No. 2-32293, and JP-B No. 2-16765, and urethane compounds having an ethyleneoxide skeleton and described in JP-B Nos. 58-49860, 56-17654, 62-39417, and 62-39418. Photopolymerizable compositions having excellent photoresponsive speed can also be obtained using addition-polymerizable compounds having an amino or sulfide structure in a molecule thereof, which are disclosed in JP-A Nos. 63-277653, 63-260909, and 01-105238. Commercially available products thereof include: urethane oligomers UAS-10 and UAB-140 (both of which are tradenames, manufactured by Nippon Paper Chemicals Co., Ltd.); UA-7200 (tradename, manufactured by Shin-Nakamura Chemical Co., Ltd.); DPHA-40H (tradename, manufactured by Nippon Kayaku Co., Ltd.); and UA-306H, UA-306T, UA-306I, AH-600, T-600, and AI-600 (all of which are tradenames, manufactured by KYOEISHA CHEMICAL Co., LTD).

Ethylenic unsaturated compounds having an acid group are also preferable, and commercially-available products thereof include TO-756 (tradename, manufactured by Toagosei Co., Ltd.), which is a trifunctional acrylate containing a carboxyl group, and TO-1382 (tradename, manufactured by Toagosei Co., Ltd.), which is a pentafunctional acrylate containing a carboxyl group. The polymerizable compound used in the invention is still more preferably a tetra- or higher-functional acrylate compound

The (C) polymerizable compound may be used singly, or in combination of two or more thereof. When two or more polymerizable compounds are used in combination, each polymerizable compound is preferably a tri- or higher-functional acrylate compound. An example of the combination is a combination of dipentaerythritol hexaacrylate and pentaerythritol triacrylate. A combination of at least one tri- or higher-functional acrylate compound and at least one ethylenic unsaturated compound having an acidic group is also preferable. The content of polymerizable compound in the black curable composition (the total content of polymerizable compounds in a case in which the black curable composition contains two or more polymerizable compounds) is preferably from 3 parts to 55 parts by mass, and more preferably from 10 parts to 50 parts by mass, assuming that the total solids content of the black curable composition is 100 parts. A content of polymerizable compound within the above range allows curing reaction to proceed sufficiently.

<Organic Solvent>

The black curable composition of the invention may generally include an organic solvent. The organic solvent is basically not particularly limited as long as the organic solvent has satisfactory properties in terms of the solubility of components and coating properties of the polymerizable composition. The organic solvent may be selected in consideration of, preferably, the solubility of the binder polymer, coating properties, and safety.

Examples of the organic solvent include:

esters such as ethyl acetate, n-butyl acetate, isobutyl acetate, amyl formate, isoamyl acetate, butyl propionate, isopropyl butyrate, ethyl butyrate, butyl butyrate, methyl lactate, ethyl lactate, alkyl oxyacetates such as methyl oxyacetates, ethyl oxyacetates, and butyl oxyacetates (such as methyl methoxyacetate, ethyl methoxyacetate, butyl methoxyacetate, methyl ethoxyacetate, and ethyl ethoxyacetate), alkyl 3-oxypropionates such as methyl 3-oxypropionates and ethyl 3-oxypropionates (such as methyl 3-methoxypropionate, ethyl 3-methoxypropionate, methyl 3-ethoxypropionate, and ethyl 3-ethoxypropionate), alkyl 2-oxypropionates such as methyl 2-oxypropionates, ethyl 2-oxypropionates, and propyl 2-oxypropionates (such as methyl 2-methoxypropionate, ethyl 2-methoxypropionate, propyl 2-methoxypropionate, methyl 2-ethoxypropionate, and ethyl 2-ethoxypropionate), methyl 2-oxy-2-methylpropionates and ethyl 2-oxy-2-methylpropionates (such as methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate;

ethers such as diethyleneglycol dimethyl ether, tetrahydrofuran, ethyleneglycol monomethyl ether, ethyleneglycol monoethyl ether, methyl cellosolve acetate, ethyl cellosolve acetate, diethyleneglycol monomethyl ether, diethyleneglycol monoethyl ether, diethyleneglycol monobutyl ether, propyleneglycol monomethyl ether, propyleneglycol monomethyl ether acetate, propyleneglycol monoethyl ether acetate, and propyleneglycol monopropyl ether acetate;

ketones such as methyl ethyl ketone, cyclohexanone, 2-heptanone, and 3-heptanone; and

aromatic hydrocarbons such as toluene and xylene.

A mixture of two or more of the above organic solvents is also preferable from the viewpoint of improving the solubility of the binder polymer and the coating surface properties. In this case, a mixture solution composed of two or more selected from methyl 3-ethoxypropionate, ethyl 3-ethoxypropionate, ethyl cellosolve acetate, ethyl lactate, diethyleneglycol dimethyl ether, butyl acetate, methyl 3-methoxypropionate, 2-heptanone, cyclohexanone, ethyl carbitol acetate, butyl carbitol acetate, propyleneglycol methyl ether, or propyleneglycol methyl ether acetate is preferable.

From the viewpoint of coating properties, the content of organic solvent in the black curable composition of the invention is preferably such that the total solids concentration of the black curable composition is from 5 to 80% by mass, more preferably from 5 to 60% by mass, and particularly preferably from 10 to 50% by mass.

<(D) Cardo Resin>

The black curable composition according to the invention includes (D) a cardo resin. The (D) cardo resin in the invention refers to a resin having a cardo structure (a skeleton structure in which two cyclic structures are bonded to a quaternary carbon atom that is a constituent atom of another cyclic structure) in a molecule thereof.

Preferable examples of cardo structures include the following structure, in which benzene rings are bonded to a fluorene ring.

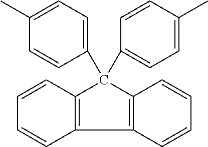

Examples of the (D) cardo resin used in the invention include a resin that is selected from an epoxy resin, a polyester resin, a polycarbonate resin, an acrylic resin, a polyether resin, a polyamide resin, a polyurea resin, a polyimide resin, a polyamide acid, or the like, and that has a cardo structure, such as the above fluorene skeleton, in a molecule thereof. Examples of the (D) cardo resin further include a reaction product of a polyfunctional epoxy or a polyfunctional acrylate, with a compound having a cardo structure having a group capable of reacting with the polyfunctional epoxy or polyfunctional acrylate (such as a carboxylic acid, a mercapto group, a hydroxy group, or an amino group).

Among the above, a resin that is selected from an epoxy resin, a polyester resin, an acrylic resin, or a polyimide resin, and that has a cardo structure, such as the above fluorene skeleton, in a molecule thereof, is particularly preferable.

The (D) cardo resin includes at least one type of cardo-structure-containing repeating unit. The (D) cardo resin may consist of at least one type of cardo-structure-containing repeating unit. The (D) cardo resin may include at least one type of cardo-structure-containing repeating unit and at least one type of repeating unit that does not contain a cardo structure.

The cardo resin in the invention can be easily synthesized by heating and agitating a commercially available compound having a cardo structure and a monomer capable of reacting with the compound in an organic solvent. After the reaction, the cardo resin solution may be used as it is, or the cardo resin for use may be taken out as a solid after adding a poor solvent to the cardo resin solution.

Specific examples of compounds having a cardo structure include, but are not limited to, the compounds shown below.

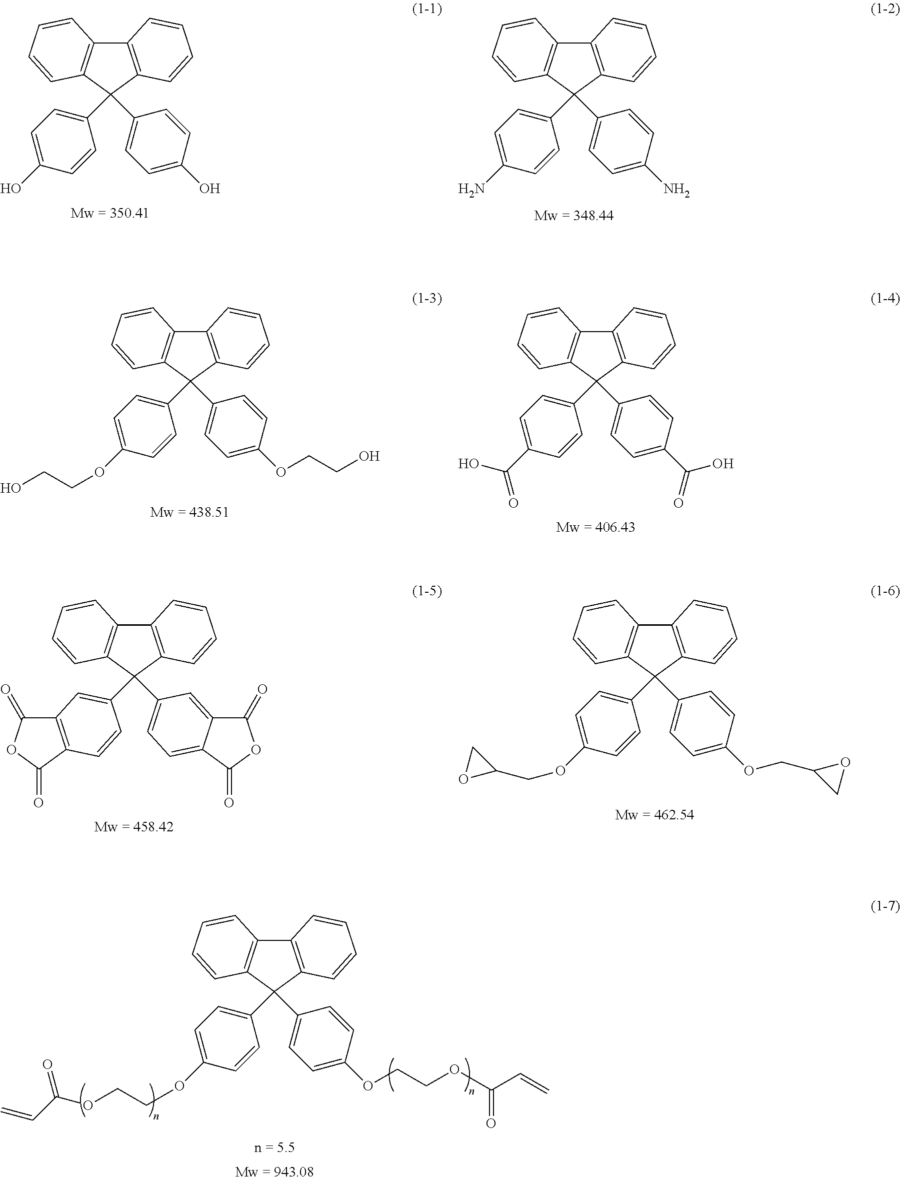

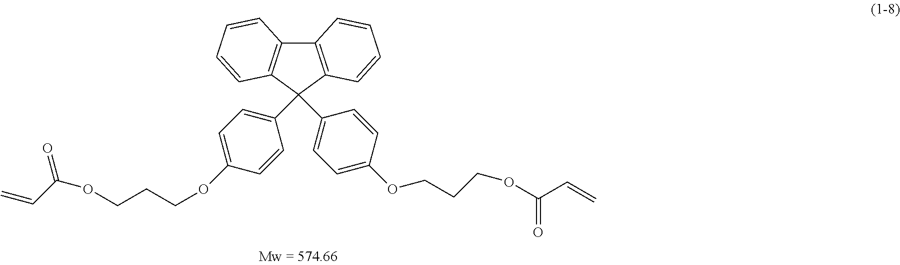

Specific examples of cardo resin compounds synthesized from a compound having the cardo structure are described in the Table 1 below. However, the cardo resin according to the invention is not limited thereto. In the table, reference numerals 1-1 to 1-8 represent residues that derive from the above exemplary structures of compounds having a cardo structure, and reference numerals 2-1 to 2-6 represent residues that derive from the compounds shown below.

TABLE 1

| | | | | | | | | | | Weight- |
|---|---|---|---|---|---|---|---|---|---|---|
| | | | | Compositional Ratio | | | Compositional Ratio | | | Average |
| | Constituent unit | | | (mole %) | | | (weight %) | | | Molecular |
| Cardo resin | A | B | C | A | B | C | A | B | C | weight |
| D-1 | 1-1 | 1-5 | — | 50 | 50 | — | 43.3 | 56.7 | — | 17,000 |
| D-2 | 1-2 | 1-5 | — | 50 | 50 | — | 43.2 | 56.8 | — | 20,000 |
| D-3 | 1-3 | 1-5 | — | 50 | 50 | — | 48.9 | 51.1 | — | 15,000 |
| D-4 | 1-2 | 2-4 | — | 50 | 50 | — | 61.5 | 38.5 | — | 12,000 |
| D-5 | 1-2 | 2-2 | — | 50 | 50 | — | 58.2 | 41.8 | — | 29,000 |
| D-6 | 1-1 | 2-1 | 2-2 | 25 | 25 | 50 | 32.5 | 21.1 | 46.4 | 16,000 |
| D-7 | 1-4 | 1-6 | — | 50 | 50 | — | 46.8 | 53.2 | — | 19,000 |
| D-8 | 1-6 | 2-3 | — | 50 | 50 | — | 73.6 | 26.4 | — | 20,000 |
| D-9 | 1-7 | 2-5 | Acrylic | 40 | 50 | 10 | 77.8 | 20.7 | 1.5 | 18,000 |
| | | | acid | | | | | | | |
| D-10 | 1-7 | 2-6 | 2-5 | 25 | 25 | 50 | 49.1 | 30.1 | 20.8 | 32,000 |
| D-11 | 1-8 | 2-6 | 2-5 | 25 | 25 | 50 | 37.0 | 37.2 | 25.8 | 22,000 |
| D-12 | 1-8 | 2-6 | 2-5 | 25 | 25 | 50 | 37.0 | 37.2 | 25.8 | 12,000 |
| D-13 | 1-8 | 2-6 | 2-5 | 25 | 25 | 50 | 37.0 | 37.2 | 25.8 | 5,000 |
| D-14 | 1-8 | 2-6 | 2-5 | 25 | 25 | 50 | 37.0 | 37.2 | 25.8 | 3,000 |
| D-15 | 1-8 | 2-5 | — | 66.7 | 33.3 | — | 85.2 | 14.8 | — | 20,000 |

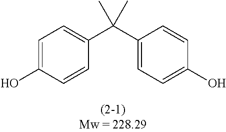

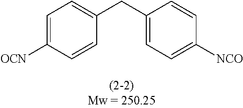

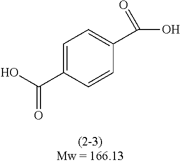

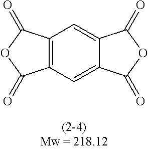

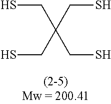

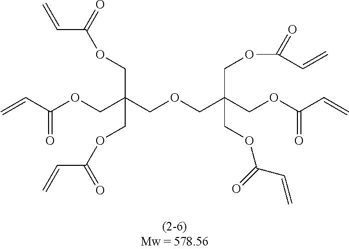

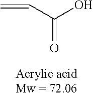

The (D) cardo resin is preferably a cardo resin containing a constituent unit derived from a compound containing a thiol group.

The thiol-group-containing compound may be a compound having from 2 to 6 thiol groups in a molecule thereof. Examples thereof include, in addition to the compound (2-5) shown above, 1,2-ethanedithiol, 1,2-propanedithiol, 1,1,1-tris(mercaptomethyl)ethane, 1,2,3,4-tetramercaptobutane, and bis[2,2,2-tris(mercaptomethyl)ethyl]ether. The content of constituent units derived from thiol-group-containing compounds in the cardo resin is preferably from 1 to 40% by mass relative to the total mass of the cardo resin.

Use of a cardo resin containing a constituent unit derived from a thiol-group-containing compound improves transparency in the UV region, and also improves the hardness of a cured film obtained by curing the black curable composition.

The (D) cardo resin in the invention may be used singly, or in combination of two or more thereof. The weight average molecular weight of the (D) cardo resin is preferably from 2,000 to 50000, and more preferably from 3,000 to 20000. Favorable developability can be obtained within the above range.

In the invention, the (D) cardo resin includes cardo structures, such as a fluorene skeleton, at a content of preferably from 30% by mass to 90% by mass, and more preferably from 40% by mass to 70% by mass, relative to the total mass of the cardo resin from the viewpoint of the degree of the decrease in transmittance when disposed on a lens.

The content of cardo resin in the black curable composition is preferably from 0.1 parts by mass to 50 parts by mass, and more preferably from 1 part by mass to 30 parts by mass, assuming that the total solids content of the black curable composition is 100 parts by mass.

<Other Additives>

In addition to the essential components (A) to (D) and an optional pigment dispersant, the black curable composition according to the invention may further include a variety of compounds, in accordance with the purpose. These optional compounds are described below.

<Binder>

If necessary, the black curable composition according to the invention may further include a binder polymer, for the purpose of, for example, improving film properties. The binder is preferably a linear organic polymer, which may be freely selected from known linear organic polymers. In order to enable development with water or a weakly alkaline aqueous solution, it is preferable to select a linear organic polymer that is soluble or swellable in water or a weakly alkaline aqueous solution. The linear organic polymer may be selected and used in consideration of not only its function as a film-forming agent, but also its function of allowing development with a developer such as water, a weakly alkaline aqueous solution, or an organic solvent.

For example, use of a water-soluble organic polymer enables water development. Examples of the linear organic polymer include radical polymerization products having a carboxylic acid group at a side chain thereof, such as those described in JP-A No. 59-44615, JP-B Nos. 54-34327, 58-12577, and 54-25957, and JP-A Nos. 54-92723, 59-53836, and 59-71048. Specific examples thereof include a resin that is a homopolymer of a carboxyl group-containing monomer, a resin that is a copolymer of monomers including a carboxyl group-containing monomer, a resin obtained by hydrolysis, half-esterification, or half-amidation of acid anhydride units of a homopolymer of an acid anhydride-containing monomer, a resin obtained by hydrolysis, half-esterification, or half-amidation of a copolymer of monomers including an acid anhydride-containing monomer, and an epoxy acrylate obtained by modifying an epoxy resin with at least one unsaturated monocarboxylic acid and at least one acid anhydride. Examples of the carboxyl group-containing monomer include acrylic acid, methacrylic acid, itaconic acid, crotonic acid, maleic acid, fumaric acid, and 4-carboxylstyrene. Examples of the acid anhydride-containing monomer include maleic anhydride.

Further examples include an acidic cellulose derivative having a carboxylic acid group at a side chain thereof, and a product obtained by adding a cyclic acid anhydride to a hydroxyl group-containing polymer.

Acid group-containing urethane polymers, such as those described in JP-B Nos. 7-120040, 7-120041, 7-120042, and 8-12424, JP-A Nos. 63-287944, 63-287947, 1-271741, and Japanese Patent Application No. 10-116232, are advantageous in terms of suitability for low exposure amount due to excellent strength thereof.

Acetal-modified polyvinyl alcohol polymers having acid groups, such as those described in European Patent Nos. 993966 and 1204000, and JP-A No. 2001-318463, are preferable in that they provide an excellent balance between film strength and developability. Examples of water-soluble linear organic polymers further include polyvinyl pyrrolidone and polyethylene oxide. An alcohol-soluble nylon or a polyether of 2,2-bis-(4-hydroxyphenyl)-propane and epichlorohydrin is also useful in terms of increasing the strength of a cured film.

Among them, a copolymer of benzyl(meth)acrylate, (meth)acrylic acid, and, optionally, one or more other addition-polymerizable vinyl monomers (preferably a copolymer of benzyl(meth)acrylate, (meth)acrylic acid, and 3-methacryloyloxy-2-hydroxypropyl methacrylate), and a copolymer of allyl(meth)acrylate, (meth)acrylic acid, and, optionally, one or more other addition-polymerizable vinyl monomers, are preferable in that they provide excellent balance between film strength, sensitivity, and developability.

A binder usable in the black curable composition has a weight average molecular weight of preferably 5,000 or more, more preferably from 10,000 to 300,000, and has a number average molecular weight of preferably 1,000 or more, more preferably from 2,000 to 250,000. The polydispersity (weight average molecular weight/number average molecular weight) thereof is preferably 1 or higher, and more preferably in the range of from 1.1 to 10.

The binder polymer may be any of a random polymer, a block polymer, a graft polymer, or the like.

Incorporation of an alkali-soluble resin having a double bond at a side chain, from among various binders, improves both of curability of exposed portions and alkali-developability of unexposed portions.

The alkali-soluble binder polymer having a double bond at a side chain optionally used in the invention has, in the structure thereof, an acid group for imparting alkali-solubility to the resin, and at least one unsaturated double bond, so as to improve various properties such as removability of non-image portions. Binder resins having such a partial structure are detailed in JP-A No. 2003-262958, and the compounds described therein may be used in the invention.

The content of binder relative to the total solids content of the black curable composition according to the invention is preferably from 0.1% by mass to 30% by mass, and more preferably from 0.3% by mass to 15% by mass, from the viewpoints of suppressing both of peeling-off of a pattern and generation of development residue.

<Colorant>

In the invention, the black curable composition may further include a colorant other than metal-containing inorganic pigments, such as a known organic pigment or dye, in order to obtain desired light-shielding properties.

Examples of colorants that may additionally be used include (E) an organic pigment such as an organic pigment selected from the pigments described in paragraphs [0030] to [0044] of JP-A No. 2008-224982, and pigments obtained by replacing at least one Cl substituent of C. I. Pigment Green 58 or C. I. Pigment Blue 79 by OH. Among them, preferable pigments that can be used in the invention include those listed below. However, pigments that can be used in the invention are not limited thereto.
C. I. Pigment Yellow 11, 24, 108, 109, 110, 138, 139, 150, 151, 154, 167, 180, 185,
C. I. Pigment Orange 36,
C. I. Pigment Red 122, 150, 171, 175, 177, 209, 224, 242, 254, 255
C. I. Pigment Violet 19, 23, 29, 32
C. I. Pigment Blue 15:1, 15:3, 15:6, 16, 22, 60, 66,
C. I. Pigment Green 7, 36, 37, 58,
C. I. Pigment Black 1

There is no particular limitation on a dye that can be used as a colorant, and known dyes may be selected and used, as appropriate. Examples thereof include dyes described in JP-A No. 64-90403, JP-A No. 64-91102, JP-A No. 1-94301, JP-A No. 6-11614, Japanese Patent No. 2592207, U.S. Pat. No. 4,808,501, U.S. Pat. No. 5,667,920, U.S. Pat. No. 5,059,500, JP-A No. 5-333207, JP-A No. 6-35183, JP-A No. 6-51115, JP-A No. 6-194828, JP-A No. 8-211599, JP-A No. 4-249549, JP-A No. 10-123316, JP-A No. 11-302283, JP-A No. 7-286107, JP-A No. 2001-4823, JP-A No. 8-15522, JP-A No. 8-29771, JP-A No. 8-146215, JP-A No. 11-343437, JP-A No. 8-62416, JP-A No. 2002-14220, JP-A No. 2002-14221, JP-A No. 2002-14222, JP-A No. 2002-14223, JP-A No. 8-302224, JP-A No. 8-73758, JP-A No. 8-179120, and JP-A No. 8-151531.

In terms of chemical structures, pyrazole azo dyes, anilino azo dyes, triphenylmethane dyes, anthraquinone dyes, anthrapyridone dyes, benzylidene dyes, oxonol dyes, pyrazolotriazole azo dyes, pyridone azo dyes, cyanine dyes, phenothiazine dyes, pyrrolopyrazole azomethine dyes, xanthene dyes, phthalocyanine dyes, benzopyran dyes, indigo dyes, pyromethene dyes, or the like may be used.

From the viewpoint of combination with the metal-containing inorganic pigment in the invention, a combination of a titanium black pigment with at least one of an orange pigment, a red pigment, or a violet pigment is preferable, and a combination of a titanium black pigment with a red pigment is most preferable, from the viewpoint of achieving both of curability and light-shielding properties.

<Sensitizer>

The black curable composition may include a sensitizer for the purpose of improvement in radical generation efficiency of the (B) polymerization initiator and/or shifting, toward a longer wavelength side, a wavelength at which black curable composition is sensitive.

The sensitizer optionally used in the invention sensitizes the (B) polymerization initiator, preferably by an electron transfer mechanism or an energy transfer mechanism.

Preferable examples of the sensitizer include compounds described in paragraphs [0085] to [0098] of JP-A No. 2008-214395.

From the viewpoints of sensitivity and storage stability, the content of sensitizer is preferably from 0.1 to 30% by mass, more preferably from 1 to 20% by mass, and still more preferably from 2 to 15% by mass, relative to the mass of the total solids content of the black curable composition.

<Polymerization Inhibitor>

It is preferable to incorporate a small amount of a polymerization inhibitor into the black curable composition, in order to prevent unnecessary thermal polymerization of the polymerizable compound during the production or storage of the composition. A known thermal polymerization inhibitor may be used as the polymerization inhibitor, and specific examples thereof include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylene bis(4-methyl-6-t-butylphenol), and N-nitrosophenylhydroxyamine cerous salt.

The content of thermal polymerization inhibitor is preferably from about from 0.01 to about 5% by mass relative to the total solids content of the black curable composition.

Further, if necessary, a higher fatty acid or a derivative thereof, such as behenic acid or behenamide, may be incorporated into the coating liquid such that the higher fatty acid derivative localizes on the surface of a coating film during drying after coating, in order to prevent polymerization inhibition due to oxygen. The total content of higher fatty acids and higher fatty acid derivatives is preferably from about 0.5 to about 10% by mass relative to the total solids content.

<Adhesion Promoter>

An adhesion promoter may be incorporated into the black curable composition in order to improve adhesion to a hard surface such as a surface of a support. Examples of the adhesion promoter include a silane coupling agent and a titanium coupling agent.

Examples of the silane coupling agent include γ-methacryloxypropyltrimethoxysilane, γ-methacryloxypropyltriethoxysilane, γ-methacryloxypropyldimethoxymethylsilane, γ-acryloxypropyltrimethoxysilane, γ-acryloxypropyltriethoxysilane, γ-mercaptopropyltrimethoxysilane, γ-aminopropyltriethoxysilane, and phenyltrimethoxysilane. Among them, γ-methacryloxypropyltrimethoxysilane is preferable.

The content of adhesion promoter is preferably from 0.5 to 30% by mass, and more preferably from 0.7 to 20% by mass, relative to the total solids content of the black curable composition.

Further, when the black curable composition according to the invention is used in the production of a lens on a glass substrate, it is preferable to add an adhesion promoter from the viewpoint of improving sensitivity.

<Surfactant>

Various surfactants may be incorporated into the black curable composition of the invention, with a view to further improving the coating properties. Examples of surfactants that may be used include fluorosurfactants, nonionic surfactants, cationic surfactants, anionic surfactants, and silicone surfactants.

In particular, the incorporation of a fluorosurfactant into the black curable composition of the invention further improves the liquid properties (particularly, fluidity) of a coating liquid formed from the black curable composition, and further improves the uniformity of the coating thickness and liquid saving properties.

Specifically, in a case in which a film is formed using a coating liquid in which a black curable composition containing a fluorosurfactant is used, wettability on a surface to be coated is improved due to decreased interfacial tension between the surface to be coated and the coating liquid, as a result of which the coating properties on the surface to be coated is improved. Therefore, the incorporation of a fluorosurfactant is effective in that a film having a substantially uniform thickness and a reduced thickness variation can be favorably formed even in a case in which the film is formed from the coating liquid in a small amount and has a small thickness of several micrometers.

The fluorine content in the fluorosurfactant is preferably from 3% by mass to 40% by mass, more preferably from 5% by mass to 30% by mass, and particularly preferably from 7% by mass to 25% by mass. A fluorosurfactant having a fluorine content within the above range is effective in terms of the uniformity of the thickness of the coating film and in terms of liquid saving properties, and provides a favorable solubility in the black curable composition.

Examples of fluorosurfactants include: MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F479, MEGAFACE F482, MEGAFACE F780, and MEGAFACE F781 (tradenames, manufactured by DIC Corporation); FLUORAD FC430, FLUORAD FC431, and FLUORAD FC171 (tradenames, manufactured by Sumitomo 3M Limited); and SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KH-40 (tradenames, manufactured by Asahi Glass Co., Ltd.).

Examples of nonionic surfactants include: polyoxyethylene lauryl ether, polyoxyethylene stearyl ether, polyoxyethylene oleyl ether, polyoxyethylene octyl phenyl ether, polyoxyethylene nonyl phenyl ether, polyethyleneglycol dilaurate, polyethyleneglycol distearate, and sorbitan fatty acid esters (such as PLURONIC L10, L31, L61, L62, 10R5, 17R2, and 25R2 and TETRONIC 304, 701, 704, 901, 904, and 150R1 (tradenames, manufactured by BASF)); and SOLSPERSE 20000 (tradename, manufactured by Lubrizol Japan Ltd.).

Examples of cationic surfactants include: phthalocyanine derivatives (an example of commercially available product thereof is EFKA-745 manufactured by Morishita Sangyo Kabushiki Gaisha); organosiloxane polymer KP341 (tradename, manufactured by Shin-Etsu Chemicals Co., Ltd.); (meth)acrylic (co)polymers POLYFLOW No. 75, No. 90, and No. 95 (tradenames, manufactured by KYOEISHA CHEMICAL Co., Ltd.); and W001 (tradename, available from Yusho Co., Ltd.).

Examples of anionic surfactants include W004, W005, and W017 (tradenames, available from Yusho Co., Ltd.).

Examples of silicone surfactants include: TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (tradenames, manufactured by Toray Silicone Company, Ltd.); TSF-4440, TSF-4300, TSF-4445, TSF-444(4)(5)(6)(7)6, TSF-4460, and TSF-4452 (tradenames, manufactured by Momentive Performance Materials Inc.); KP341 (tradename, manufactured by Shin-Etsu Chemicals Co., Ltd.); and BYK323 and BYK330 (tradenames, manufactured by BYK-Chemie).

The surfactant may be used singly, or in combination of two or more thereof.

<Other Components>

Further, the black curable composition may include a cosensitizer, for the purposes of further improving the sensitivity of the sensitizing dye and/or initiator to actinic radiation, or suppressing the inhibition of polymerization of the photopolymerizable compound due to oxygen. Further, if necessary, a known additive such as a diluent, a plasticizer, or an oleophilizing agent may be added to the black curable composition according to the invention in order to improve the physical properties of a cured film.

The black curable composition according to the invention may be prepared by preparing a mixture of the aforementioned (A) metal-containing inorganic pigment (preferably in the form of a pigment-dispersed composition further containing a pigment dispersant), (B) polymerization initiator, (C) polymerizable compound, (D) cardo resin, and, optionally, a variety of additives and a solvent.

The black curable composition according to the invention, having the above configuration, cures with high sensitivity and is capable of forming a light-shielding film having excellent light-shielding properties.

The black curable composition according to the invention is useful in the formation of a light-shielding film for a wafer-level lens. Further, additional use of an alkali-soluble binder facilitates formation of a higher-resolution light-shielding pattern.

<Wafer-Level Lens>

The wafer-level lens according to the invention has a light-shielding film obtained by curing the black curable composition according to the invention, at a peripheral portion of a lens disposed on a substrate.

The wafer-level lens according to the invention is described below in detail.

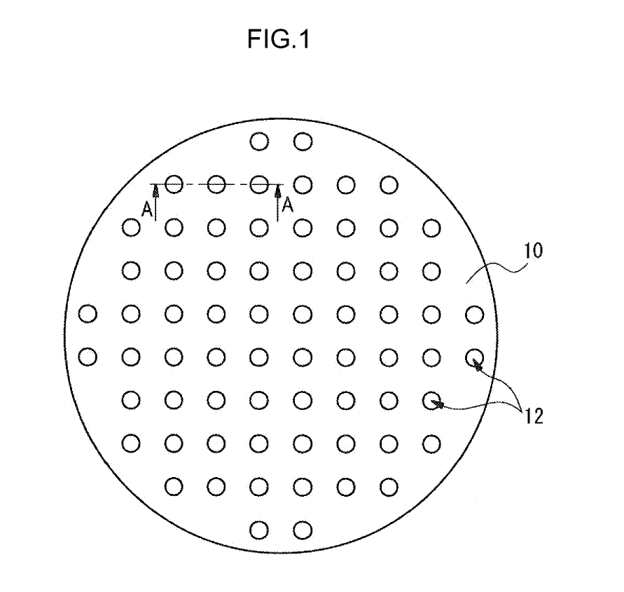

FIG. 1 is a plan view showing an example of the configuration of a wafer-level lens array having plural wafer-level lenses.

As shown in FIG. 1, the wafer-level lens array includes a substrate 10, and lenses 12 arranged on the substrate 10. In FIG. 1, the plural lenses 12 are aligned two-dimensionally on the substrate 10. However, the plural lenses may alternatively be aligned one-dimensionally on the substrate 10. A light-shielding film 14 that prevents light transmission through other regions than the lenses is provided at areas between the plural lenses 12.

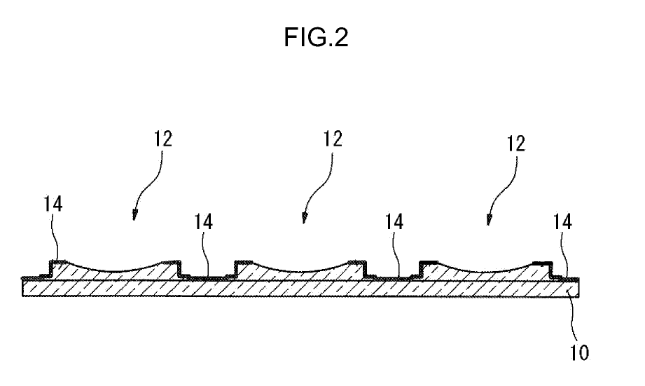

FIG. 2 is a cross-sectional view taken along line A-A shown in FIG. 1.

As shown in FIG. 2, in the wafer-level lens array, a light-shielding film 14 is provided between the plural lenses 12 arranged on the substrate 10, and prevents light transmission at regions other than lenses 12.

The wafer-level lens according to the invention includes one lens 12 disposed on the substrate 10, and the light-shielding film 14 provided at a peripheral portion of the lens 12. The black curable composition according to the invention is used for the formation of the light-shielding film 14.

The structure of a wafer-level lens array in which plural lenses 12 are arranged two-dimensionally on the substrate 10 as shown in FIG. 1 is described below as an example.

The lenses 12 are generally made of the same material as that of the substrate 10, and have been integrally molded on the substrate 10, or molded as a separate structure and then fixed onto the substrate.

The above configuration is only an example, and the configuration of the wafer-level lens of the invention is not limited thereto. Various embodiments may be adopted; for example, the lenses may have a multi-layer structure, and lens modules may be separated out by dicing.

The material for forming the lenses 12 is, for example, glass. Glass, of which types are so many to allow selection of a glass having high refractive index, is suitable as a material of a lens that is desired to have high optical power. Further, glass is advantages also in that glass has excellent thermal resistance, and tolerate reflow mounting onto an image pickup unit or the like.

Another example of the material for forming the lenses 12 is a resin. Resins exhibit excellent processability, and are therefore suitable for simple and inexpensive formation of lens faces using a mold.

It is preferable to use an energy-curable resin for the formation of the wafer-level lens. The energy-curable resin may be either a thermally curable resin or a resin which is cured by irradiation of an actinic energy radiation (for example, heat, ultraviolet rays, or electron beam irradiation).

In consideration of reflow mounting of an image pickup unit, the resin preferably has a relatively high softening point, for example 200° C. or higher. A resin having a softening point of 250° C. or higher is more preferable.

In the following, resins suitable as lens materials are described in detail.

Examples of the UV-curable resin include a UV-curable silicon resin, a UV-curable epoxy resin, and an acrylic resin. The epoxy resin to be used may have a linear expansion coefficient of from 40 to 80 [10⁻⁶/K], and a refractive index of from 1.50 to 1.70 (preferably from 1.50 to 1.65).

Examples of the thermosetting resin include a thermosetting silicon resin, a thermosetting epoxy resin, a thermosetting phenol resin, and a thermosetting acrylic resin. For example, the silicon resin to be used may have a linear expansion coefficient of from 30 to 160 [10⁻⁶/K], and a refractive index of from 1.40 to 1.55. The epoxy resin to be used may have a linear expansion coefficient of from 40 to 80 [10⁻⁶/K], and a refractive index of from 1.50 to 1.70 (preferably from 1.50 to 1.65). The phenol resin to be used may have a linear expansion coefficient of from 30 to 70 [10⁻⁶/K], and a refractive index of from 1.50 to 1.70. The acrylic resin to be used may have a linear expansion coefficient of from 20 to 60 [10⁻⁶/K], and a refractive index of from 1.40 to 1.60 (preferably from 1.50 to 1.60).

The thermosetting resin may be a commercially available product, specific examples of which include SMX-7852 and SMX-7877 (tradenames, manufactured by Fuji Polymer Industries Co., Ltd.), IVSM-4500 (tradename, manufactured by Toshiba Corporation), and SR-7010 (tradename, manufactured by Dow Corning Toray Co., Ltd.).

Examples of the thermoplastic resin include a polycarbonate resin, a polysulfone resin, and a polyethersulfone resin. The polycarbonate to be used may have a linear expansion coefficient of from 60 to 70 [10⁻⁶/K], and a refractive index of from 1.40 to 1.70 (preferably from 1.50 to 1.65). The polysulfone resin may have a linear expansion coefficient of from 15 to 60 [10⁻⁶/K], and a refractive index of 1.63. The polyether sulfone resin to be used may have a linear expansion coefficient of from 20 to 60 [10⁻⁶/K], and a refractive index of 1.65.

In general, optical glass has a linear expansion coefficient of from 4.9 to 14.3 [10⁻⁶/K] at 20° C., and a refractive index of from 1.4 to 2.1 at a wavelength of 589.3 nm. Quartz glass has a linear expansion coefficient of from 0.1 to 0.5 [10⁻⁶/K], and a refractive index of about 1.45.

The curable resin composition that can be used for forming a lens preferably has a moderate fluidity before curing, from the viewpoint of moldability such as capability of being molded to reflect the mold shape. Specifically, the resin is preferably liquid at normal temperature, and has a viscosity of preferably from about 1,000 mPa·s to about 50,000 mPa·s.

The curable resin composition that can be used for forming a lens preferably has such a thermal resistance as to prevent thermal deformation after curing even when subjected to a reflow process. From this viewpoint, the glass transition temperature of the cured product is preferably 200° C. or higher, more preferably 250° C. or higher, and particularly preferably 300° C. or higher. In order to impart such a high thermal resistance to the resin composition, it is necessary to restrain the motion at the molecular level. Examples of effective methods include (1) a method of increasing the cross-linking density per unit volume, (2) a method of using a resin having a robust ring structure (for example, an alicyclic structure such as cyclohexane, norbornane, or tetracyclododecane, an aromatic ring structure such as benzene or naphthalene, cardo structure such as 9,9′-biphenyl fluorene, a resin having a spiro structure such as spirobiindane, specifically, for example, resins described in JP-A 9-137043, JP-A 10-67970, JP-A No. 2003-55316, JP-A No. 2007-334018, JP-A No. 2007-238883, etc.), (3) a method of uniformly dispersing a high-Tg material such as inorganic particles (described in, for example, JP-A 5-209027, JP-A 10-298265, etc.). Plural methods from among the above methods may be used in combination. Control of the thermal resistance is preferably performed within the range in which other characteristics such as fluidity, shrinkage ratio, and refractive index are not impaired.

From the viewpoint of the transfer accuracy of the shape, a curable resin composition that exhibits low volume shrinkage during curing reaction is preferable. The curing shrinkage of the resin composition is preferably 10% or less, more preferably 5% or less, and particularly preferably 3% or less.

Examples of the resin composition exhibiting a low curing shrinkage include:

(1) a resin composition containing a high-molecular-weight curing agent (such as prepolymer), examples of which are described in JP-A No. 2001-19740, JP-A No. 2004-302293, JP-A No. 2007-211247, and the like; the number average molecular weight of the high-molecular-weight curing agent is preferably in the range of from 200 to 100,000, more preferably from 500 to 50,000, and particularly preferably from 1,000 to 20,000, and the value of (the number average molecular weight/the number of reactive groups for curing) of the curing agent is preferably in the range of from 50 to 10,000, more preferably from 100 to 5000, and particularly preferably from 200 to 3000;

(2) a resin composition containing a non-reactive material (such as organic/inorganic particles or non-reactive resins), examples of which are described in JP-A 6-298883, JP-A 2001-247793, JP-A 2006-225434, and the like;

(3) a resin composition containing a low-shrinkage cross-linking reactive group, examples of which include a ring-opening polymerizable group (such as an epoxy group (described in, for example, JP-A No. 2004-210932), an oxetanyl group (described in, for example, JP-A 8-134405), an episulfide group (described in, for example, JP-A No. 2002-105110), or a cyclic carbonate group (described in, for example, JP-A 7-62065)), an ene/thiol curable group (described in, for example, JP-A No. 2003-20334), or a hydrosilylated curable group (described in, for example, JP-A No. 2005-15666);

(4) a resin composition containing a resin having a rigid skeleton (such as fluorene, adamantane, or isophorone), examples of which are described in, for example, JP-A 9-137043;

(5) a resin composition containing two types of monomer having respectively different polymerizable groups and forming an interpenetrating network structure (so-called IPN structure), examples of which are described in, for example, JP-A No. 2006-131868; and

(6) a resin composition containing a swellable material, examples of which are described in, for example, JP-A No. 2004-2719 and JP-A No. 2008-238417. These resin compositions can be suitably used in the invention. Combined use of plural curing-shrinkage reducing methods from among the above (for example, combined use of a prepolymer containing a ring-opening polymerizable group and a resin composition containing fine particles) is preferable from the viewpoint of optimizing physical properties.

It is preferable to use two or more resin compositions having different Abbe numbers (including a high Abbe-number resin and a low Abbe-number resin) for forming the wafer-level lens according to the invention.

The high Abbe-number resin preferably has an Abbe number (νd) of 50 or more, more preferably 55 or more, and particularly preferably 60 or more. The refractive index (nd) thereof is preferably 1.52 or higher, more preferably 1.55 or higher, and particularly preferably 1.57 or higher.

The high Abbe-number resin contained in the resin composition is preferably an aliphatic resin, and particularly preferably a resin having an alicyclic structure (for example, a resin having a ring structure such as cyclohexane, norbornane, adamantane, tricyclodecane, or tetracyclododecane, specific examples of which include resins described in JP-A 10-152551, JP-A No. 2002-212500, JP-A No. 2003-20334, JP-A No. 2004-210932, JP-A No. 2006-199790, JP-A No. 2007-2144, JP-A No. 2007-284650, and JP-A No. 2008-105999).

The low Abbe-number resin preferably has an Abbe number (νd) of 30 or less, more preferably 25 or less, and particularly preferably 20 or less. The refractive index (nd) thereof is preferably of 1.60 or higher, more preferably 1.63 or higher, and particularly preferably 1.65 or higher.

The low Abbe-number resin is preferably a resin having an aromatic structure, examples of which include a resin containing a structure such as 9,9′-diarylfluorene, naphthalene, benzothiazole, or benzotriazole. Specific examples thereof include resins described in JP-A 60-38411, JP-A 10-67977, JP-A No. 2002-47335, JP-A No. 2003-238884, JP-A No. 2004-83855, JP-A No. 2005-325331, JP-A No. 2007-238883, International Publication No. WO 2006/095610, and Japanese Patent No. 2537540.

It is also preferable to use an organic-inorganic composite material, in which inorganic particles are dispersed in a matrix, in the resin composition used for the formation of the wafer-level lens. The use of the organic-inorganic composite material may aim at increasing the refractive index or adjusting the Abbe number.

Examples of the inorganic particles in the organic-inorganic composite material include oxide particles, sulfide particles, selenide particles, and telluride particles. More specific examples include zirconium oxide particles, titanium oxide particles, zinc oxide particles, tin oxide particles, niobium oxide particles, cerium oxide particles, aluminum oxide particles, lanthanum oxide particles, yttrium oxide particles, and zinc sulfide particles.

The inorganic particles to be used may include only one type of inorganic particles, or a combination of two or more types of inorganic particles. The inorganic particles may include particles of a composite of plural ingredients.

For various purposes such as reduction of photocatalytic activity and reduction of water absorptivity, the inorganic particles may be doped with a metal other than the substance of the inorganic particles, the surfaces of the inorganic particles may be covered with a metal oxide, such as silica or alumina, other than the substance of the inorganic particles, and/or the surfaces of the inorganic particles may be modified with a silane coupling agent, a titanate coupling agent, an organic acid (such as a carboxylic acid, a sulfonic acid, a phosphoric acid, or a phosphonic acid), or a dispersant having an organic acid group.

The number average primary particle size of the inorganic particles is typically in the range of from 1 nm to 1,000 nm. If the number average primary particle size of the inorganic particles is excessively small, the properties of the material may alter. If the number average primary particle size of the inorganic particles is excessively large, effects of Rayleigh scattering are significant. Accordingly, the number average primary particle size of the inorganic particles is preferably in the range of from 1 nm to 15 nm, more preferably from 2 nm to 10 nm, and particularly preferably from 3 nm to 7 nm. Further, a narrower particle size distribution of the inorganic particles is more preferable. Although there are many ways of defining such monodispersed particles, the numerical range defined in JP-A No. 2006-160992 is an example of a preferable range of particle diameter distribution.

Here, the number average primary particle size can be measured, for example, by X-ray diffraction (XRD), small-angle X-ray scattering (SAXS), X-ray diffuse scattering (XDS), grazing-incidence small-angle X-ray scattering (GI-SAX), a scanning electron microscope (SEM), or a transmission electron microscope (TEM).

The refractive index of the inorganic particles at 22° C. and a wavelength of 589.3 nm is preferably in the range of from 1.90 to 3.00, more preferably from 1.90 to 2.70, and particularly preferably from 2.00 to 2.70.

In the organic-inorganic composite material, the content of inorganic particles relative to the resin serving as matrix is preferably 5% by mass or more, more preferably from 10 to 70% by mass, and particularly preferably from 30 to 60% by mass, from the viewpoint of transparency and provision of high refractive index.

Any of the UV-curable resin, the thermosetting resin, the thermoplastic resin, the high Abbe-number resin, or the low Abbe-number resin described as the material of the wafer-level lens in the above may be used as a resin for forming a matrix, which is used in the organic-inorganic composite material. Further examples of the resin for forming a matrix include: a resin having a refractive index higher than 1.60, such as those described in JP-A No. 2007-93893; a block copolymer including a hydrophobic segment and a hydrophilic segment, such as those described in JP-A No. 2007-211164; a resin having, at a polymer terminal or at a side chain, a functional group capable of forming a chemical bond with inorganic particles, such as those described in JP-A Nos. 2007-238929, 2010-043191, 2010-065063, and 2010-054817, and a thermoplastic resin as described in JP-A Nos. 2010-031186 and 2010-037368.

If necessary, an additive such as a plasticizer or a dispersant may be added to the organic-inorganic composite material.

Preferable combinations of a resin serving as a matrix and inorganic fine particles include the following combinations.

In a case in which a high Abbe-number resin, such as those described above, is used to form a matrix, it is preferable to disperse inorganic particles of, for example, lanthanum oxide, aluminum oxide, or zirconium oxide. In a case in which a low Abbe-number resin is used to form a matrix, it is preferable to disperse inorganic particles of, for example, titanium oxide, tin oxide, or zirconium oxide.

In order to uniformly disperse inorganic particles, it is preferable to use, for example, a dispersant containing a functional group having reactivity with a monomer for forming the matrix (such as those described in working examples of JP-A No. 2007-238884), a block copolymer including a hydrophobic segment and a hydrophilic segment (such as those described in JP-A No. 2007-211164), or a resin having, at a polymer terminal or at a side chain, a functional group capable of forming a chemical bond with the inorganic particles (such as those described in JP-A No. 2007-238929 and JP-A No. 2007-238930), as appropriate.

Further, the resin composition used for the formation of the wafer-level lens may include an additive as appropriate, examples of which include known release agents such as silicon-based release agents, fluorine-based release agents, and compounds containing a long-chain alkyl group, and antioxidants such as hindered phenol.

The resin composition used for the formation of the wafer-level lens may include a curing catalyst or initiator, as necessary. Specific examples thereof include a compound that promotes a curing reaction (radical polymerization or ionic polymerization) by the action of heat or an actinic energy radiation, such as those described in paragraph numbers [0065] to [0066] of JP-A No. 2005-92099. The content of the curing reaction promoter may vary depending on the type of catalyst or initiator, the difference in reactive sites for curing, or the like, and cannot be uniquely limited. In general, the content of curing reaction promoter is preferably in the range of from 0.1 to 15% by mass, and more preferably from 0.5 to 5% by mass, relative to the total solids content of the resin composition.

The resin composition used in the production of the wafer-level lens according to the invention can be prepared by appropriately mixing the above-described ingredients. Separate addition of a solvent is unnecessary in a case in which the liquid low-molecular-weight monomer (reactive diluent) or the like is capable of dissolving other components. If this is not the case, the resin composition can be prepared by dissolving the components using a solvent. The solvent optionally used in the resin composition is not particularly limited as long as a homogenous solution or dispersion can be formed with the solvent without precipitation of the composition, and the solvent may be appropriately selected. Specific examples of the solvent include ketones (such as acetone, methyl ethyl ketone, and methyl isobutyl ketone), esters (such as ethyl acetate and butyl acetate), ethers (such as tetrahydrofuran and 1,4-dioxane), alcohols (such as methanol, ethanol, isopropyl alcohol, butanol, and ethylene glycol), aromatic hydrocarbons (such as toluene and xylene), and water. When the resin composition contains a solvent, it is preferable to perform, after casting of the composition on a substrate and/or a mold and drying of the solvent, a mold shape transfer operation.

The material of the substrate 10 may be selected from the above-described molding materials usable for forming the lenses 12. The substrate 10 may be formed from the same material as the molding material for forming the lenses 12. However, as long as the substrate 10 is formed from a material that is transparent to visible light, such as glass, the material of the substrate 10 may be different from the molding material for forming the lenses 12. In this case, the material for forming the substrate 10 is preferably a material having a linear expansion coefficient that is equal to or extremely close to that of the material for forming the lenses 12. If the linear expansion coefficient of the material forming the lenses 12 is identical or close to that of the material forming the substrate 10, distortion or cracking of the lenses 12 that occurs during heating due to difference in linear expansion rate is suppressed in the process of reflow mounting the wafer-level lenses on an image pickup unit.

Although not shown in FIGS. 1 and 2, an infrared filter (IR filter) may be formed on the light incidence side of the substrate 10.

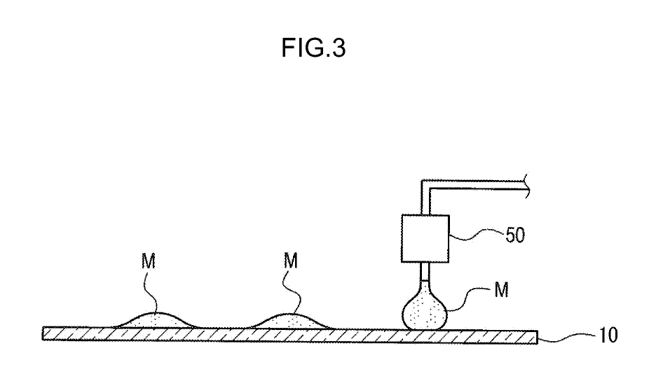

The configuration and the production of the wafer-level lens is specifically described below with reference to FIGS. 3 to 8, using an exemplary production method of a wafer-level lens array.

[The Configuration and Production of Wafer-Level Lens (1)]

### —Formation of Lenses—

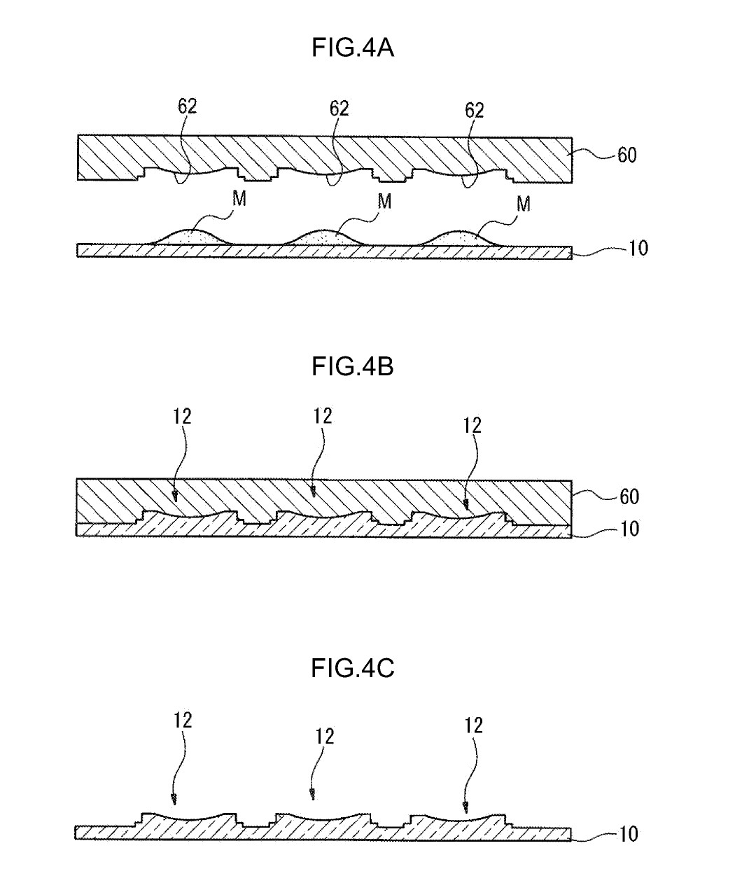

First, a method of forming lenses 12 on a substrate 10 is described with reference to FIG. 3 and FIGS. 4A to 4C. Elements having substantially the same function and action are denoted by the same reference numeral throughout the drawings, and overlapping descriptions therefor are sometimes omitted.

FIG. 3 is a view showing a state in which a molding material (designated by “M” in FIG. 3), which is a resin composition for lens formation, is supplied to a substrate 10.

FIGS. 4A to C are views showing an procedure for forming the lenses 12 on the substrate 10 by using a mold 60.

As shown in FIG. 3, the molding material M is dripped on regions of the substrate 10 at which lenses are to be formed, using a dispenser 50. Here, an amount of the molding material M corresponding to one lens 12 is provided to each region to be supplied with the molding material.

After the molding material M is supplied to the substrate 10, a mold 60 for forming lenses is disposed at a side of the substrate 10 at which the molding material M has been supplied, as shown in FIG. 4A. The mold 60 is provided with depressed areas 62 for forming the shape of the lenses 12 by transfer, in accordance with the desired number of the lenses 12.

As shown in FIG. 4B, the mold 60 is pressed against the molding material M on the substrate 10, and the molding material M is deformed to conform to the shape of depressed areas 62. While the mold 60 is pressed against the molding material M, the molding material M is cured by irradiating heat or ultraviolet rays from the outside of the mold 60 in a case in which the molding material M is a thermosetting resin or a UV curable resin.

After the molding material M is cured, the substrate 10 and the lenses 12 are released from the mold 60, as shown in FIG. 4C.

### —Formation of Light-Shielding Film—

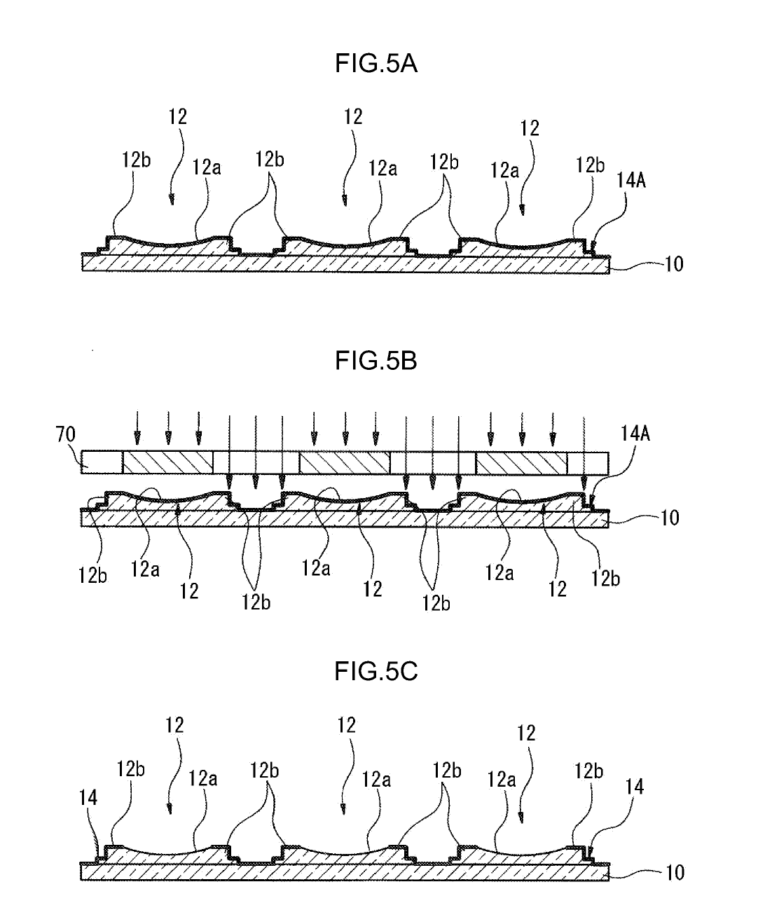

Next, a method of forming a light-shielding film 14 at peripheral regions of the lenses 12 is described below with reference to FIGS. 5A to 5C.

FIGS. 5A to 5C are schematic cross-sectional views showing a process of providing a light-shielding film 14 on the substrate 10 on which the lenses 12 have been formed.

The method of forming a light-shielding film 14 includes a light-shielding coating layer formation process of coating the black curable composition according to the invention on the substrate 10 to form a light-shielding coating layer 14A (see FIG. 5A), a light exposure process of patternwise exposing the light-shielding coating layer 14A to light through a mask 70 (see FIG. 5B), and a development process of developing the light-shielding coating layer 14A after the light exposure to remove uncured portions, thereby forming a patterned light-shielding film 14 (see FIG. 5C).

The formation of the light-shielding film 14 may be carried out before or after production of the lenses 12, without particular limitation. In the following, a method of forming the light-shielding film 14 after the production of lenses 12 is described in detail.

Individual processes of the method of producing the light-shielding film 14 are described below.

<Light-Shielding Coating Layer Formation Process>

In the light-shielding coating layer formation process, as shown in FIG. 5A, the black curable composition is coated on the substrate 10, thereby forming the light-shielding coating layer 14A formed from the black curable composition and exhibiting a low light reflection ratio. Here, the light-shielding coating layer 14A is formed to completely cover the lens-side surface of the substrate 10 and the surfaces of lens faces 12a and lens periphery portions 12b of the lenses 12.

The substrate 10 used in the present process is not particularly limited, and examples thereof include soda-lime glass, alkali-free glass, PYREX (registered trademark) glass, quartz glass, and transparent resins.

As used herein, the substrate 10 refers to a structure including both the substrate 10 and the lens(es) 12 in an embodiment in which the lens(es) 12 and the substrate 10 are integrally formed.

Further, an undercoat layer may be provided on the substrate 10 as necessary in order to improve adhesion to an upper layer, to prevent diffusion of a material, or to flatten the surface of the substrate 10.

As a method of coating the substrate 10 and the lenses 12 with the black curable composition, various types of coating method such as slit coating, a spray coating method, an inkjet method, spin coating, cast coating, roll coating, and a screen printing method may be employed.

The film thickness of the black curable composition immediately after coating thereof is preferably in the range of from 0.1 μm to 10 μm, more preferably from 0.2 μm to 5 μm, and still more preferably from 0.2 μm to 3 μm, from the viewpoints of film thickness uniformity of the coated film and ease of drying of the coating solvent.

Drying (pre-baking) of the light-shielding coating layer 14A coated on the substrate 10 may be carried out at a temperature of from 50° C. to 140° C. for from 10 to 300 seconds using, for example, a hot plate or an oven.

The coating film thickness of the black curable composition after drying (hereinafter, referred to as “dry film thickness” in some cases) may be freely selected in consideration of desired performance such as light shielding properties, and is typically in the range of from 0.1 μm to less than 50 μm.

<Light Exposure Process>

In the light exposure process, the light-shielding coating layer 14A formed through the light-shielding coating layer formation process is subjected to patternwise light exposure. Although the patternwise light exposure may be scanning light exposure, it is preferable that the patternwise light exposure is conducted by light exposure through the mask 70 having a predetermined mask pattern, as shown in FIG. 5B.

In the light exposure in the present process, the patternwise light exposure of the light-shielding coating layer 14A may be carried out by light exposure through a predetermined mask pattern; as a result of the light exposure, only light-irradiated portions of the light-shielding coating layer 14A are cured. Here, a mask pattern to be used is a mask pattern with which the surfaces of the lens periphery portions 12b and the surface of the substrate 10 at a region between the lenses 12 are irradiated with light. In this manner, the light irradiation causes curing of the light-shielding coating layer 14A only in the other region than the lens faces 12a, and the cured region will form light-shielding films 14.

Preferable examples of radiations that can be used for the light exposure include ultraviolet radiations such as g-line, h-line, and i-line. The light source for the radiation used for the light exposure may be a single-wavelength light source, or a light source that emits light containing all wavelength components, such as a high-pressure mercury lamp.

<Development Process>

Subsequent to the light exposure process, an alkali development treatment (development process) is carried out, thereby dissolving portions that have not been irradiated with light in the light exposure process—that is, uncured regions of the light-shielding coating layer 14A—are dissolved in an alkaline aqueous solution, and leaving only portions that have been cured by the light irradiation.

More specifically, the development of the light-shielding layer 14A, which has been exposed to light as shown in FIG. 5B, results in removal of only the portions of the light-shielding coating layer 14A that are formed on the lens faces 12a, and formation of the cured light-shielding film 14 at the other regions as shown in FIG. 5C.

Examples of the alkali agent contained in the developer (alkaline aqueous solution) used in the development process include an organic alkali agent, an inorganic alkali agent, and a combination thereof. In the light-shielding film formation in the invention, an organic alkali agent is preferable from the viewpoint of suppression of damage to, for example, neighboring circuits.

Examples of the alkali agent used in the developer include organic alkaline compounds (organic alkali agents) such as aqueous ammonia, ethylamine, diethylamine, dimethylethanolamine, tetramethylammonium hydroxide, tetraethylammonium hydroxide, choline, pyrrole, piperidine, and 1,8-diazabicyclo-[5.4.0]-7-undecene; and inorganic compounds (inorganic alkali agents) such as sodium hydroxide, potassium hydroxide, sodium hydrogen carbonate, and potassium hydrogen carbonate. An alkaline aqueous solution in which an alkali agent, such as those described above, is diluted with pure water so as to have a concentration of from 0.001% by mass to 10% by mass, and preferably from 0.01% by mass to 1% by mass, is preferable for use as the developer.

The development temperature is usually in the range of from 20° C. to 30° C., and the development time is usually in the range of from 20 to 90 seconds.

In a case in which a developer formed of such an alkaline aqueous solution is used, washing (rinsing) with pure water is generally carried out after unexposed portions of the coated film are removed by the developer. Specifically, after the development treatment, the developer is removed by sufficient washing with pure water, and the substrate having the light-shielding coating layer is subjected to a drying process.

If necessary, the production process may further include, after the light-shielding coating layer formation process, light exposure process, and development process are carried out, a curing process of curing the formed light-shielding film (light-shielding pattern) by heating (post-baking) and/or exposing to light.

The post-baking is a heat treatment conducted after development in order to complete the curing, and is usually a thermal curing treatment at from 100° C. to 250° C. The conditions such as the temperature and time of the post-baking can be appropriately set depending on the material of the substrate 10 or lens 12. For example, when the substrate 10 is glass, the post-baking temperature is preferably from 180° C. to 240° C., from within the above-specified temperature range.

The post-baking treatment may be carried out on the resultant light-shielding film 14 after development, in a continuous manner or batchwise manner using a heating device such as a hot plate, a convection oven (hot air circulation type dryer), or a high-frequency heater under the above-described post-baking conditions.

In the above procedure, although a case in which the shape of the lenses 12 is a concave shape is described as an example, the shape of the lenses 12 is not particularly limited, and may be a convex shape or an aspheric shape. In the above procedure, although a wafer-level lens having plural lenses 12 formed on one side of the substrate 10 is described as an example, a configuration in which plural lenses 12 are formed on both sides of the substrate 10 may be adopted. In this case, a patterned light-shielding film 14 is formed on the region other than the lens faces, on both sides.

[Configuration and Production of Wafer-Level Lens (2)]

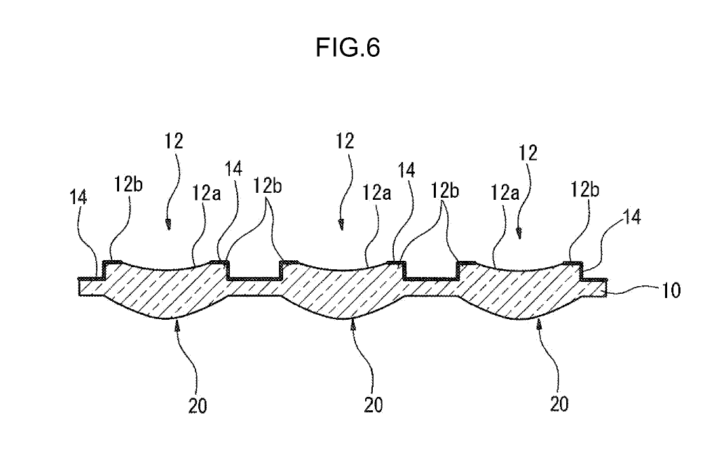

FIG. 6 is a view showing another configuration example of the wafer-level lens array.

The wafer-level lens shown in FIG. 6 has a configuration (monolithic type) in which the substrate 10 and the lenses 12 are simultaneously molded using the same molding material.

When producing wafer-level lenses of this type, the molding material may be selected from the above-described molding materials. In this example, plural concave lenses 12 are formed on one side of the substrate 10 (upper side in FIG. 6), and plural convex lens 20 are formed on the other side of the substrate 10 (lower side in FIG. 6). The region other than the lens face 12a of the substrate 10, that is, the surface of the substrate 10 and the surfaces of the lens periphery portions 12b are provided with a patterned light-shielding film 14. The patterning procedure described above may be applied as the patterning method for forming the light-shielding film 14.

[Configuration and Production of Wafer-Level Lens (3)]

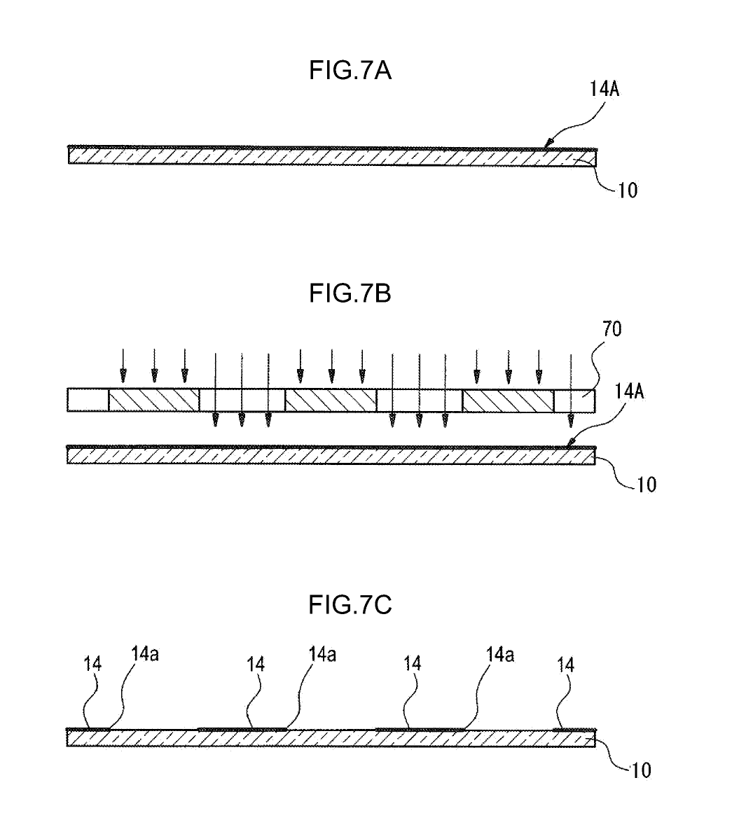

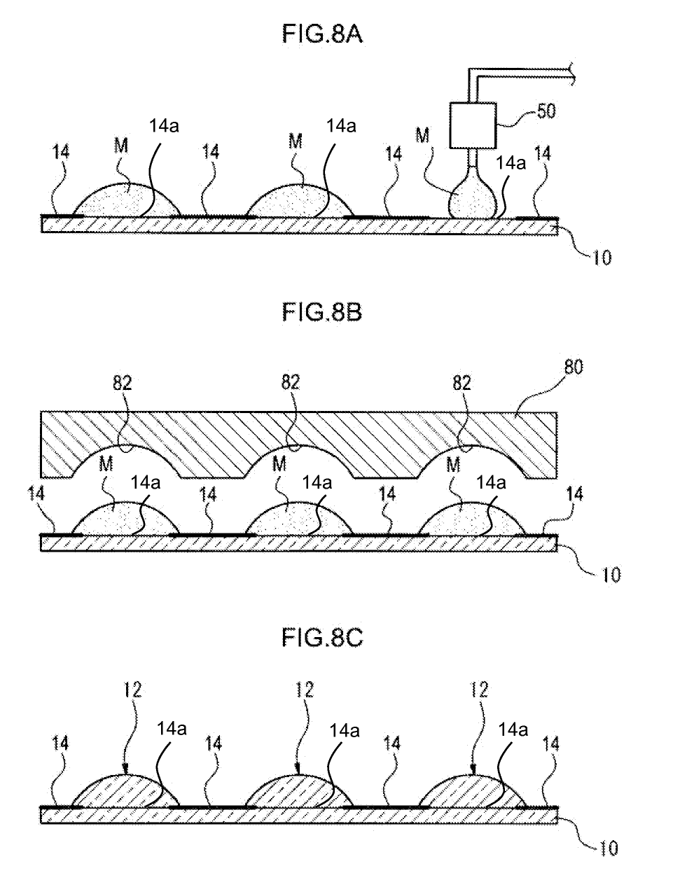

Next, another example of the configuration of the wafer-level lens array and a procedure for producing the wafer-level lens array of this configuration are described with reference to FIGS. 7A to 7C and FIGS. 8A to 8C.

FIGS. 7A to 7C are schematic views showing another process of forming the patterned light-shielding film 14.

FIGS. 8A to 8C are schematic views showing a process of forming the lenses 12 after the formation of the patterned light-shielding film 14.

In the examples of the wafer-level lens array shown in FIGS. 3 to 6, the patterned light-shielding film 14 is formed on the substrate 10 provided with the lenses 12. In contrast, in the following procedure, the patterned light-shielding film 14 is first formed on a substrate 10, and then the lenses 12 are formed on the substrate 10 by molding.

—Formation of Light-Shielding Film—

First, as shown in FIG. 7A, a light-shielding coating layer formation process of forming the light-shielding coating layer 14A is carried out by coating the black curable composition on the substrate 10.

Then, drying of the light-shielding coating layer 14A coated on the substrate 10 is carried out at a temperature of from 50° C. to 140° C. for from 10 to 300 seconds, using a hot plate, an oven, or the like. The dry film thickness of the black curable composition may be appropriately selected depending on desired performance such as light shielding properties, and the dry film thickness of the black curable composition is typically in the range of from 0.1 μm to less than 50 μm.

Then, as shown in FIG. 7B, a light exposure process of patternwise exposing the light-shielding coating layer 14A, which has been formed through the light-shielding coating layer formation process, to light through a mask 70 is carried out. The mask 70 has a predetermined mask pattern. In the light exposure in this process, the light-shielding coating layer 14A is patternwise exposed to light, thereby curing only portions of the light-shielding coating layer 14A that have been irradiated with light. Here, the mask pattern to be used is a mask pattern with which the light-shielding coating layer 14A is irradiated with light only in the region other than portions that are to become lens apertures 14a of the lenses 12 when the lenses 12 are shaped in a subsequent process. In this manner, the light-shielding coating layer 14A is cured by irradiation with light only in the region other than the portions that are to become lens apertures 14a of the lenses 12. As in the above-described procedure, preferable examples of radiations that can be used for the light exposure include ultraviolet lights such as g-line, h-line, and i-line.

Subsequently, an alkali development treatment (development process) is carried out. As a result, the light-shielding coating layer 14A is dissolved in an alkaline aqueous solution only in the regions corresponding to the lens apertures 14a of the lenses 12, which are portions of the light-shielding coating layer 14A that have not been cured in the patternwise light exposure. In addition, the photo-cured light-shielding coating layer 14A in the region other than the portions corresponding to the lens apertures 14a of the lenses 12 remains on the substrate 10 to form a light-shielding film 14 (see FIG. 7C).

The alkali agent contained in the aqueous alkaline solution as the developer may be selected from the above-described alkali agents usable in the above-described procedure.

After the development, the developer is removed by washing, followed by drying.

Also in this embodiment, after the light-shielding coating layer formation process, the light exposure process, and the development process are carried out, a curing process of curing the formed light-shielding film by the above-described post-baking and/or light exposure may be carried out, if necessary.

—Formation of Lens—

Next, a process of forming the lenses 12 after the formation of the light-shielding film 14 is described.

As shown in FIG. 8A, the molding material M for forming the lenses 12 is dripped on the substrate 10 on which the patterned light-shielding film 14 has been formed, using a dispenser 50. The molding material M is supplied so as to cover the region corresponding to the lens aperture 14a of each lens 12 and partially cover end portions of the light-shielding film 14 that are adjacent to the lens aperture 14a.

After the molding material M is supplied to the substrate 10, a mold 80 for forming lenses is disposed at a side of the substrate 10 at which the molding material M has been supplied, as shown in FIG. 8B. The mold 80 is provided with depressed areas 82 for transferring the shape of the lenses 12, according to the desired number of the lenses 12.

The mold 80 is pressed against the molding material Mon the substrate 10, thereby deforming the molding material M to conform to the shape of the depressed areas. While the mold 80 is pressed against the molding material M, the molding material M is cured by irradiating heat or ultraviolet rays from the outside of the mold in a case in which the molding material M is a thermosetting resin or a UV curable resin.

After the molding material M is cured, the substrate 10 and the lenses 12 are released from the mold 80, and wafer-level lenses having a patterned light-shielding film 14 is formed on the substrate 10, as shown in FIG. 8C.

As described above, the configuration of the patterned light-shielding film 14 provided on the wafer-level lens is not limited to the configuration shown in FIG. 5 in which the light-shielding film 14 is provided in the region other than the lens faces 12a of the lenses 12, and the configuration shown in FIG. 8C in which the light-shielding film 14 is provided in the region other than the lens apertures 14a of the lenses 12 may alternatively be adopted.

In the wafer-level lens, the light-shielding film 14 exhibiting a low light-reflection ratio is formed in pattern on at least one surface of the substrate 10. The thus-formed light-shielding film sufficiently shields light in the region other than the lens faces 12a or lens apertures 14a of the lenses 12, and inhibits the generation of reflected light. Accordingly, when the wafer-level lens is applied to an image pickup module equipped with a solid-state image pickup device, problems in image pickup such as ghost or flare caused by reflected light can be prevented.

Further, since the light-shielding film 14 is disposed on a surface of the substrate, there is no need to attach an additional light-shielding member to the wafer-level lens, as a result of which an increase in production costs can be avoided.

In a configuration in which a structure having an irregular surface is provided around the lens such as the configuration disclosed in International Publication No. WO 2008/102648, the light incident on the structure is reflected or diverged, which may cause a problem such as ghost. In consideration of this, a configuration may be adopted in which a patterned light-shielding film 14 is provided in the region other than the lens faces 12a of the lenses 12 as shown in FIG. 5; this configuration enables shielding of light in the region other than the lens faces 12a, thereby improving optical performance.

### EXAMPLES

The invention is more specifically described below by reference to examples. However, the invention is not limited to the following examples as long as the gist of the invention is maintained. Hereinafter, “part(s)” and “%” represent “part(s) by mass” and “% by mass”, respectively, unless otherwise specified.

[Synthesis of Cardo Resins]

(Synthesis of Exemplary Compound D-11)

10 g of 9,9′-bis(4-acryloyloxypropyloxy)phenylfluorene (the following compound 1-8), 1 g of dipentaerythritol hexaacrylate (the following compound 2-6), and 2.3 g of tetramercaptomethyl methane (the following compound 2-5) were dissolved in 13.3 g of propylene glycol methyl ether acetate (hereinafter referred to as PGMEA), and agitated at 85° C. for 4 hours, as a result of which Exemplary Compound D-11, which is a reaction product of the above ingredients, was obtained at a solids content of 50%. It was confirmed by ¹H-NMR that the obtained compound was a cardo resin of Exemplary Compound D-11, and the weight-average molecular weight thereof was measured by gel permeation chromatography (GPC).

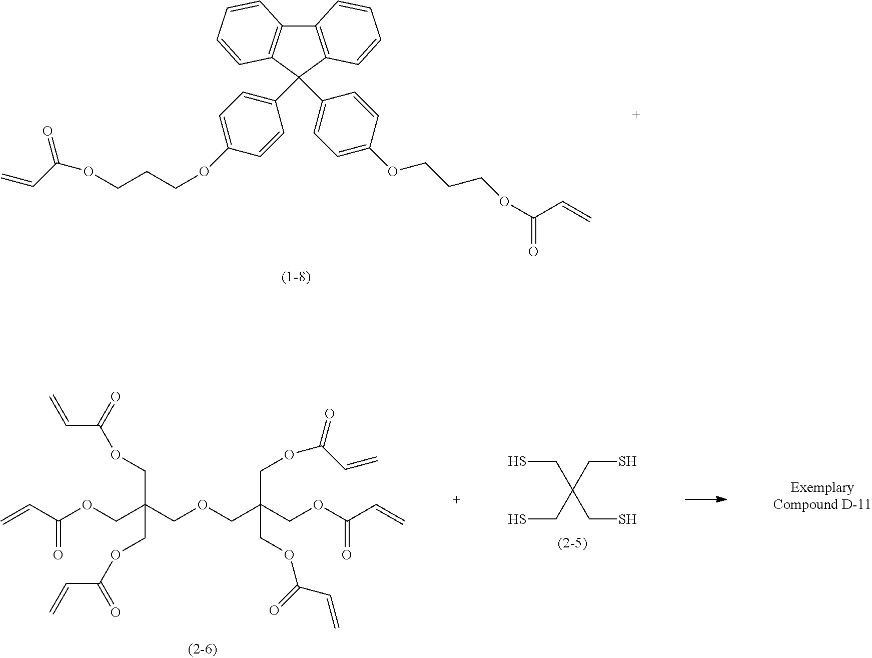

(Synthesis of Exemplary Compounds D-1 to D-10 and D-12 to D-15)

Exemplary Compounds D-1 to D-10 and D-12 to D-15 were synthesized in a manner similar to the synthesis of Exemplary Compound D-11, the identity of the obtained compounds was confirmed with ¹H-NMR, and the weight-average molecular weight thereof was measured by gel permeation chromatography (GPC).

(Preparation of Dispersion Liquid)

The ingredients of the following Composition I were subjected to high-viscosity dispersing treatment using two-roll mill, as a result of which a dispersion was obtained.

### (Composition I)

| | |
|---|---|
| Titanium black (13M-C (tradename) manufactured by Mitsubishi Materials Corporation, having an average | 40 parts |
| primary particle diameter of 75 nm): | |
| Dispersant B-1 (having the following structure, 30% solution in PGMEA): | 5 parts |

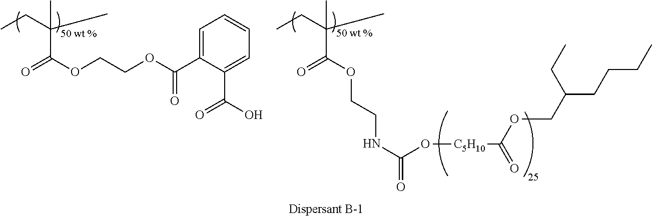

The ingredients of the following Composition II were added to the obtained dispersion, and the resultant mixture was agitated using a homogenizer at 3,000 rpm for 3 hours. The resultant mixture solution was subjected to fine dispersing treatment for 4 hours using a disperser (DISPERMAT (tradename) manufactured by VMA-GETZMANN GMBH) with zirconia beads having a diameter of 0.3 mm as a dispersion medium, as a result of which a titanium black dispersion liquid (hereinafter referred to as “TB dispersion liquid 1”) was obtained.

(Composition II)

| | |
|---|---|
| 30% solution of dispersant B-1 in PGMEA: | 20 parts |
| PGMEA as solvent: | 150 parts |

(Preparation of Black Curable Composition B-1 to B-20 and B-23 to B-25)

The following ingredients were mixed by an agitator so as to prepare black curable compositions of B-1 to B-20 and B-23 to B-25.

| | | |
|---|---|---|
| Dispersion liquid: dispersion liquid indicated in Table 2 | 24 | parts |
| (TB dispersion liquid 1) | | |
| Cardo resin: exemplary compound indicated in Table 2 | 5.0 | parts |
| Binder: binder indicated in Table 2 (30% solution in PGMEA) | 10 | parts |
| Polymerizable compound: dipentaerythritol hexaacrylate | 2.0 | parts |
| Polymerizable compound: pentaerythritol triacrylate | 1.0 | part |
| Polymerization initiator: compound indicated in Table 2 | 0.3 | parts |
| Solvent: PGMEA | 10 | parts |
| Solvent: ethyl 3-ethoxypropionate | 8 | parts |

<Preparation of Black Curable Composition B-21>

(Preparation of Silver Tin Composition)

15 g of tin colloid (average particle diameter: 20 nm, solids content: 20%, manufactured by Sumitomo Osaka Cement Company, Limited), 60 g of silver colloid (average particle diameter: 7 nm, solids content: 20%, manufactured by Sumitomo Osaka Cement Company, Limited), and a solution of 0.75 g of polyvinylpyrrolidone dissolved in 100 mL of water were added to 200 mL of pure water maintained at 60° C., as a result of which a colloid solution was obtained.

Then, the colloid solution was agitated for 60 minutes during which the colloid solution was maintained at 60° C. Thereafter, the colloid solution was irradiated with ultrasonic waves for 5 minutes. Then, the colloid solution was concentrated by centrifugal separation, thereby providing a Liquid A having a solids content of 25%. The Liquid A was freeze-dried, thereby providing a powder sample.

A silver tin dispersion liquid was prepared in a manner similar to the preparation of TB dispersion liquid 1, using the obtained powder sample instead of titanium black, and using dispersant B-1. Further, a black curable composition using silver tin composition was prepared in the same manner as the preparation of the black curable composition B-11, except for using the silver tin dispersion liquid instead of the titanium black dispersion liquid.

<Preparation of Black Curable Composition B-22>

(Preparation of Red Pigment Dispersion Liquid)

A composition composed of the following ingredients was subjected to fine dispersing treatment for 4 hours using a disperser (DISPERMAT (tradename) manufactured by VMA-GETZMANN GMBH) with zirconia beads having a diameter of 0.3 mm as a dispersion medium, as a result of which a red pigment dispersion liquid was obtained.

| | |
|---|---|
| Colorant: C.I. Pigment Red 254 | 30 parts |
| Binder: benzyl methacrylate/methacrylic acid/hydroxyethyl | 10 parts |
| methacrylate copolymer (molar ratio: 80/10/10, Mw: 10000, | |
| solvent: PGMEA, solids content: 40%) | |
| Solvent: PGMEA | 200 parts |
| Dispersant: 30% solution of Dispersant B-1 in PGMEA | 30 parts |

A black curable composition B-22 was prepared in the same manner as the preparation of the black curable composition B-11, except that the dispersion liquid was replaced by 20 parts of TB dispersion liquid 1 and 4 parts of the red pigment dispersion liquid.

<Preparation of Black Curable Composition B-26>

A black curable composition B-26 was prepared in the same manner as the preparation of the black curable composition B-11, except that the 24 parts of the titanium black dispersion liquid used in the preparation of the black curable composition B11 was replaced by 53.4 parts of a carbon black dispersion liquid (K-042884-2 (tradename) manufactured by TOYO INK MFG. CO., LTD., containing carbon black in an amount of 19.4% by mass, dispersant in an amount of 8.9% by mass, cyclohexanone in an amount of 16.1% by mass, and propyleneglycol monomethyl ether acetate in an amount of 55.6% by mass).

Table 2 shows the ingredients used for the preparation of the black curable compositions B-1 to B-26. Binder resins (E-1) and (E-2) and polymerization initiators used for the preparation are the compounds shown below.

TABLE 2

| | | | | Polym- |
|---|---|---|---|---|
| Black curable | | | | erization |
| composition | Dispersion liquid | Cardo resin | Binder | initiator |
| B-1 | TB dispersion liquid 1 | D-1 | (E-1) | 1-24 |
| B-2 | TB dispersion liquid 1 | D-2 | (E-1) | 1-24 |
| B-3 | TB dispersion liquid 1 | D-3 | (E-1) | 1-24 |
| B-4 | TB dispersion liquid 1 | D-4 | (E-1) | 1-24 |
| B-5 | TB dispersion liquid 1 | D-5 | (E-1) | 1-24 |
| B-6 | TB dispersion liquid 1 | D-6 | (E-1) | 1-24 |
| B-7 | TB dispersion liquid 1 | D-7 | (E-1) | 1-24 |
| B-8 | TB dispersion liquid 1 | D-8 | (E-1) | 1-24 |
| B-9 | TB dispersion liquid 1 | D-9 | (E-1) | 1-24 |
| B-10 | TB dispersion liquid 1 | D-10 | (E-1) | 1-24 |
| B-11 | TB dispersion liquid 1 | D-11 | (E-1) | 1-24 |
| B-12 | TB dispersion liquid 1 | D-11 | (E-1) | 1-25 |
| B-13 | TB dispersion liquid 1 | D-11 | (E-1) | 1-26 |
| B-14 | TB dispersion liquid 1 | D-11 | (E-1) | 1-27 |
| B-15 | TB dispersion liquid 1 | D-11 | (E-1) | 1-21 |
| B-16 | TB dispersion liquid 1 | D-11 | (E-1) | 1-22 |
| B-17 | TB dispersion liquid 1 | D-12 | (E-1) | 1-24 |
| B-18 | TB dispersion liquid 1 | D-13 | (E-1) | 1-24 |
| B-19 | TB dispersion liquid 1 | D-14 | (E-1) | 1-24 |
| B-20 | TB dispersion liquid 1 | D-15 | (E-1) | 1-24 |
| B-21 | Silver tin dispersion | D-11 | (E-1) | 1-24 |
| | liquid | | | |
| B-22 | TB dispersion liquid 1/ | D-11 | (E-1) | 1-24 |
| | red pigment dispersion | | | |
| | liquid | | | |
| B-23 | TB dispersion liquid 1 | D-11 | (E-2) | 1-24 |
| B-24 | TB dispersion liquid 1 | Not added | (E-1) | 1-24 |
| B-25 | TB dispersion liquid 1 | (E-1) | (E-1) | 1-24 |
| B-26 | Carbon black | D-11 | (E-1) | 1-24 |
| | dispersion liquid | | | |

The polymerization initiators described in Table 2 (I-21, I-22, and I-24 to I-27) are exemplary compounds that are shown above and designated by the same reference characters.

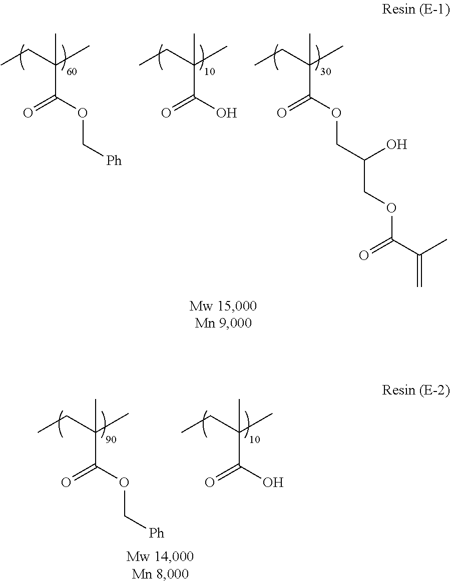

[Evaluation of Developability (Residue) on Lens Film]

(Production and Evaluation of Light-Shielding Film for Wafer-Level Lens)

A resin film was formed using the curable composition for forming a lens film, through the following operations. The resin film was used to evaluate adhesion of the resin film to the black curable composition in order to evaluate adhesion between the black curable composition and the lense.

(Formation of Thermally-Curable Resin Film for Lens Film)

The compound described in the column of “Ingredient 2” in Table 3 in an amount indicated in the column of “Ingredient 2” was added to Ingredient 1, thereby preparing curable compositions 1 to 6 for forming a lens film. In a case in which the column of “Ingredient 2” for a curable composition for forming a lens film is blank, only Ingredient 1 was used to prepare the curable composition.

The curable compositions 1 to 4 (2 mL) shown in Table 3 were respectively applied to 5 cm×5 cm glass substrates (BK7 (tradename) manufactured by SCHOTT AG, having a thickness of 1 mm), and were cured by heating at 200° C. for 1 minute, thereby providing films (films 1 to 4) with which residue on a lens can be evaluated.

(Formation of Photo-Curable Resin Film for Lens Film)

Curable compositions 5 and 6 (2 mL) described in Table 3 were respectively applied to 5 cm×5 cm glass substrates (BK7 (tradename) manufactured by SCHOTT AG, having a thickness of 1 mm), and were cured by irradiating a light at 3,000 mJ/cm² using a metal halide lamp, thereby providing films (films 5 and 6) with which residue on a lens can be evaluated.

TABLE 3

| Curable | | | |
|---|---|---|---|
| compositions for | | | |
| forming lens | | | |
| film | Ingredient 1 | Ingredient 2 | Kind of film formed |
| 1 | DOW CORNING(R) SR 7010 (tradename, manufactured | | Thermally-curable |
| | by Dow Corning Corporation) | | silicone resin film |
| 2 | 1,10-decanediol diacrylate (NK ESTER A-DOG (tradename) | Di t-butyl peroxide (1% by mass) | Thermally-curable |
| | manufactured by Shin-Nakamura Chemical Co., Ltd.) | | acrylic resin film |
| 3 | Alicyclic bisphenol A type liquid epoxy resin (YX8000 | | Thermally-curable |
| | (tradename) manufactured by Japan Epoxy Resins Co., Ltd. | | epoxy resin film |
| 4 | Poly(diallyl phthalate) (BA901 (tradename) manufactured by | | Thermally-curable |
| | Showadenko K. K.) | | allyl resin film |
| 5 | Trimethylolpropane tri(meth)acrylate (ARONICS M-309 | 1-hydroxycyclohexyl phenyl ketone | Photo-curable |
| | (tradename) manufactured by Toagosei Co., Ltd.) | (0.1% by mass) | acrylic resin film |
| 6 | Alicyclic epoxy resin (EHPE-3150 (tradename) manufactured | Arylsulfonium salt derivative (SP-172, | Photo-curable |
| | by Daicel Chemical Industries, Ltd.) | manufactured by Adeka Corporation) | epoxy resin film |
| | | (1% by mass) | |

### Examples 1 to 28 and Comparative Examples 1 to 8

### Formation of Black Curable Composition Layer on Lens Film

The black curable composition described in Table 2 was applied, by spin coating, to the glass substrate having the curable resin film for forming a lens film, and then heated on a hot plate at 120° C. for 2 minutes, thereby forming a black curable composition layer. The curable resin film was subjected to puddle development at 23° C. for 60 seconds by using a 0.3% aqueous solution of tetramethyl ammonium hydroxide. Thereafter, rinsing was performed by spin shower, followed by washing with pure water and drying.

The combination of the black curable composition and the curable resin film for forming a lens film employed in each of Examples 1 to 28 and Comparative examples 1 to 8 is shown in Table 4.

(Evaluation of Residue on Lens Film)

The transmittance of the lens film at a wavelength of 900 nm before providing the black curable composition layer was measured and represented by T1(%), and the transmittance of the lens films at 900 nm when development, washing, and drying had been performed after providing the black curable composition layer was measured and represented by T2(%). The decrease in the transmittance was determined according to the following formula:

Decrease in the transmittance of the lens film (%)=T2(%)−T1(%)

Basically, the decrease in the transmittance of the lens film was caused by residual black curable composition layer on the lens film. A larger decrease in the transmittance indicates the black curable composition is left, at larger extent, on the lens film.

TABLE 4

| | | Curable | Decrease in |
|---|---|---|---|
| | Black | composition | transmittance |
| | curable | for forming | of lens |
| | composition | lens film | film (%) |
| Example 1 | B-1 | 1 | 1.0 |
| Example 2 | B-1 | 2 | 1.1 |
| Example 3 | B-1 | 3 | 1.0 |
| Example 4 | B-1 | 4 | 0.9 |
| Example 5 | B-1 | 5 | 0.7 |
| Example 6 | B-1 | 6 | 0.8 |
| Example 7 | B-2 | 1 | 0.7 |
| Example 8 | B-3 | 1 | 1.1 |
| Example 9 | B-4 | 1 | 1.3 |
| Example 10 | B-5 | 1 | 1.6 |
| Example 11 | B-6 | 1 | 2.2 |
| Example 12 | B-7 | 1 | 1.2 |
| Example 13 | B-8 | 1 | 1.3 |
| Example 14 | B-9 | 1 | 1.9 |
| Example 15 | B-10 | 1 | 1.4 |
| Example 16 | B-11 | 1 | 0.7 |
| Example 17 | B-12 | 1 | 0.9 |
| Example 18 | B-13 | 1 | 2.1 |
| Example 19 | B-14 | 1 | 0.2 |
| Example 20 | B-15 | 1 | 0.5 |
| Example 21 | B-16 | 1 | 0.2 |
| Example 22 | B-17 | 1 | 0.6 |
| Example 23 | B-18 | 1 | 0.4 |
| Example 24 | B-19 | 1 | 0.2 |
| Example 25 | B-20 | 1 | 0.9 |
| Example 26 | B-21 | 1 | 1.9 |
| Example 27 | B-22 | 1 | 1.2 |
| Example 28 | B-23 | 1 | 1.1 |
| Comparative example 1 | B-24 | 1 | 7.9 |
| Comparative example 2 | B-25 | 1 | 5.9 |
| Comparative example 3 | B-25 | 2 | 6.9 |
| Comparative example 4 | B-25 | 3 | 7.0 |
| Comparative example 5 | B-25 | 4 | 6.9 |
| Comparative example 6 | B-25 | 5 | 6.5 |
| Comparative example 7 | B-25 | 6 | 7.2 |
| Comparative example 8 | B-26 | 1 | 9.5 |

### Examples 29 to 51 and Comparative Examples 9 to 11

### Formation and Evaluation of Light Shielding Film on Glass Substrate

Each black curable composition was directly applied to glass substrates (BK7 (tradename) manufactured by SCHOTT AG, having a thickness of 1 mm) by spin coating, and then was heated on a hot plate at 120° C. for 2 minutes, thereby providing a black curable composition layer. Then, the obtained composition layer was exposed to light through a photomask having a 50 μm-hole pattern, using a high-pressure mercury lamp at exposure amounts varied from 100 mJ/cm² to 1,000 mJ/cm² at an increment of 50 mJ/cm².

The composition layer after the exposure to light was subjected to puddle development at 23° C. for 60 seconds by using a 0.3% aqueous solution of tetramethyl ammonium hydroxide. Then, rinsing by spin shower was performed, followed by washing with pure water, as a result of which a patterned light-shielding film was obtained.

The lower limit of exposure amount at which peeling was not observed in the resultant light-shielding film under an optical microscope was determined as minimum required exposure amount. A decrease in the minimum required exposure amount indicates more effective adhesion.

(Evaluation of Residue on Glass Substrate)

The transmittance of the glass substrate at a wavelength of 900 nm before providing the black curable composition layer was measured and represented by T3(%), and the transmittance of the glass substrate at 900 nm in a region from which the black curable composition layer that had not been exposed to light was removed by development was measured and represented by T4(%). The decrease in the transmittance of the glass substrate was determined according to the following formula:

Decrease in the transmittance of the glass substrate (%)=T4(%)−T2(%)

Basically, the decrease in the transmittance of the glass substrate was caused by residual black curable composition layer on the glass substrate. A larger decrease in the transmittance indicates the black curable composition is left, at larger extent, on the glass substrate

(Measurement of Transmittance of Light-Shielding Film)

The transmittance of the light-shielding film formed in a region that had been exposed to light was measured at a wavelength of 900 nm.

Throughout the Examples, transmittance was measured using a spectrophotometer (type UV-3600 (tradename) manufactured by Shimadzu Corporation).

TABLE 5

| | | Minimum | | Trans- |
|---|---|---|---|---|
| | | required | Degree of | mittance |
| | Curable | exposure | decrease in | of light- |
| | compo- | amount | transmittance | shielding |
| | sitions | (mJ/cm²) | on glass (%) | films |
| Example 29 | B-1 | 150 | 0.8 | 0.6 |
| Example 30 | B-2 | 150 | 0.9 | 0.6 |
| Example 31 | B-3 | 150 | 1.1 | 0.6 |
| Example 32 | B-4 | 150 | 1.6 | 0.6 |
| Example 33 | B-5 | 150 | 1.9 | 0.6 |
| Example 34 | B-6 | 150 | 1.4 | 0.6 |
| Example 35 | B-7 | 150 | 1.3 | 0.6 |
| Example 36 | B-8 | 150 | 1.6 | 0.6 |
| Example 37 | B-9 | 150 | 1.7 | 0.6 |
| Example 38 | B-10 | 150 | 1.3 | 0.6 |
| Example 39 | B-11 | 150 | 0.5 | 0.6 |
| Example 40 | B-12 | 150 | 0.9 | 0.6 |
| Example 41 | B-13 | 150 | 1.3 | 0.6 |
| Example 42 | B-14 | 150 | 0.8 | 0.6 |
| Example 43 | B-15 | 150 | 0.5 | 0.6 |
| Example 44 | B-16 | 150 | 0.4 | 0.6 |
| Example 45 | B-17 | 150 | 2.6 | 0.6 |
| Example 46 | B-18 | 150 | 1.5 | 0.6 |
| Example 47 | B-19 | 150 | 2.1 | 0.6 |
| Example 48 | B-20 | 150 | 0.8 | 0.6 |
| Example 49 | B-21 | 220 | 2.6 | 0.6 |
| Example 50 | B-22 | 150 | 1.5 | 0.5 |
| Example 51 | B-23 | 200 | 2.1 | 0.6 |
| Comparative example 9 | B-24 | 300 | 7.5 | 0.7 |
| Comparative example | B-25 | 250 | 6.9 | 0.6 |
| 10 | | | | |
| Comparative example | B-26 | 450 | 7.9 | 0.9 |
| 11 | | | | |

From the results of Tables 4 and 5, it will be understood that the amount of residues on various lens films or glass substrates is decreased when the black curable composition according to the invention is used. In addition, it will be understood, from the comparison of Examples 29 to 48 with Example 49 and Comparative example 11, that incorporation of titanium black as a metal-containing inorganic pigment imparts a particularly superior curing sensitivity, and, from Example 50, it will be understood that combined use of titanium black and red organic pigment further improves light-shielding properties.

Japanese Patent Application No. 2010-9760 filed on Jan. 20, 2010, is incorporated herein by reference.

All publications, patent applications, and technical standards mentioned in this specification are herein incorporated by reference to the same extent as if each individual publication, patent application, or technical standard was specifically and individually indicated to be incorporated by reference.

1. A black curable composition for a wafer-level lens comprising (A) a metal-containing inorganic pigment, (B) a polymerization initiator, (C) a polymerizable compound, and (D) a cardo resin.

2. The black curable composition for a wafer-level lens according to claim 1, wherein the (A) metal-containing inorganic pigment comprises titanium black.

3. The black curable composition for a wafer-level lens according to claim 1,
wherein the (D) cardo resin is a resin selected from the group consisting of an epoxy resin, a polyester resin, a polycarbonate resin, an acrylic resin, a polyether resin, a polyamide resin, a polyurea resin, and a polyimide resin, and wherein the (D) cardo resin has a fluorene skeleton.

4. The black curable composition for a wafer-level lens according to claim 3, wherein the fluorene skeleton included in the (D) cardo resin has the following structure:

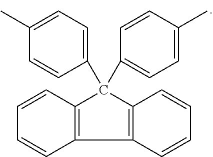

5. The black curable composition for a wafer-level lens according to claim 1, wherein the (D) cardo resin comprises a constituent unit derived from a compound that contains a thiol group.

6. The black curable composition for a wafer-level lens according to claim 1, wherein a proportion of cardo structures in the (D) cardo resin is from 30% by mass to 90% by mass relative to a total mass of the cardo resin.

7. The black curable composition for a wafer-level lens according to claim 1, wherein the (D) cardo resin consists of at least one type of cardo-structure-containing repeating unit.

8. The black curable composition for a wafer-level lens according to claim 1, wherein the (D) cardo resin includes at least one type of cardo-structure-containing repeating unit and at least one type of repeating unit that does not contain a cardo structure.

9. The black curable composition for a wafer-level lens according to claim 1, wherein the molecular weight of the (D) cardo resin is from 3,000 to 20,000.

10. The black curable composition for a wafer-level lens according to claim 1, wherein the (B) polymerization initiator comprises an oxime initiator.

11. The black curable composition for a wafer-level lens according to claim 1, wherein the (B) polymerization initiator is selected from the group consisting of the following compounds (I-1) to (I-27):

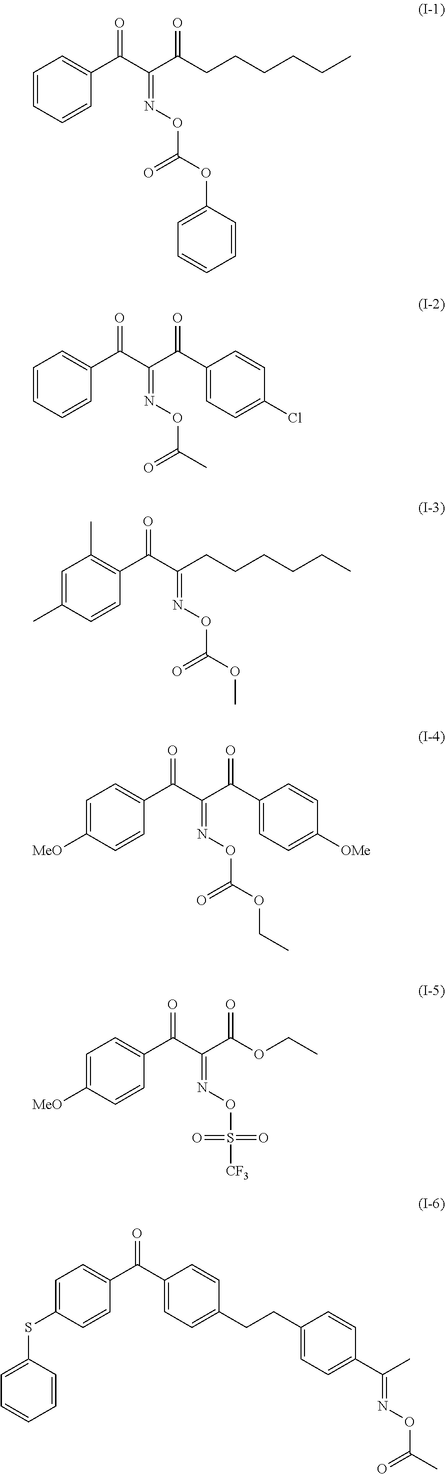

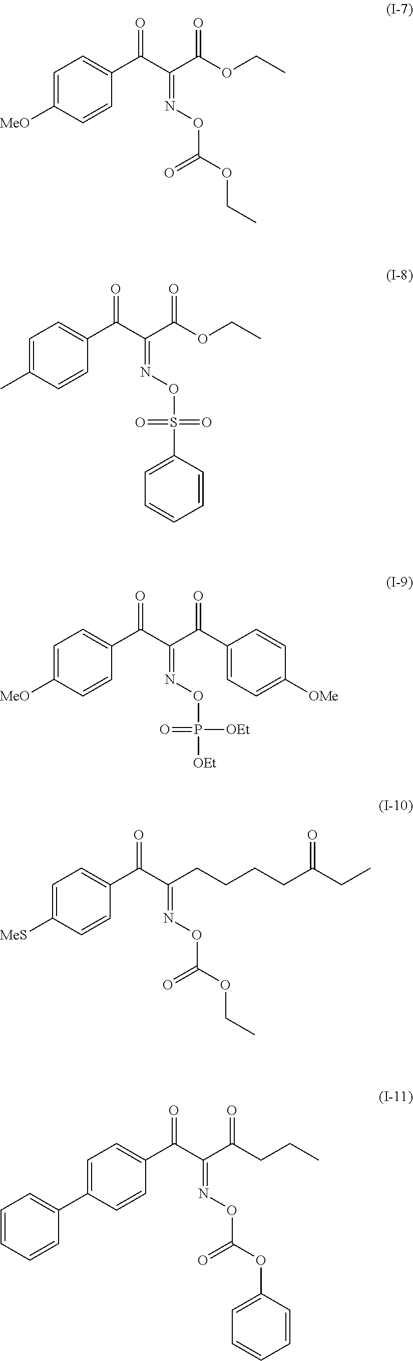

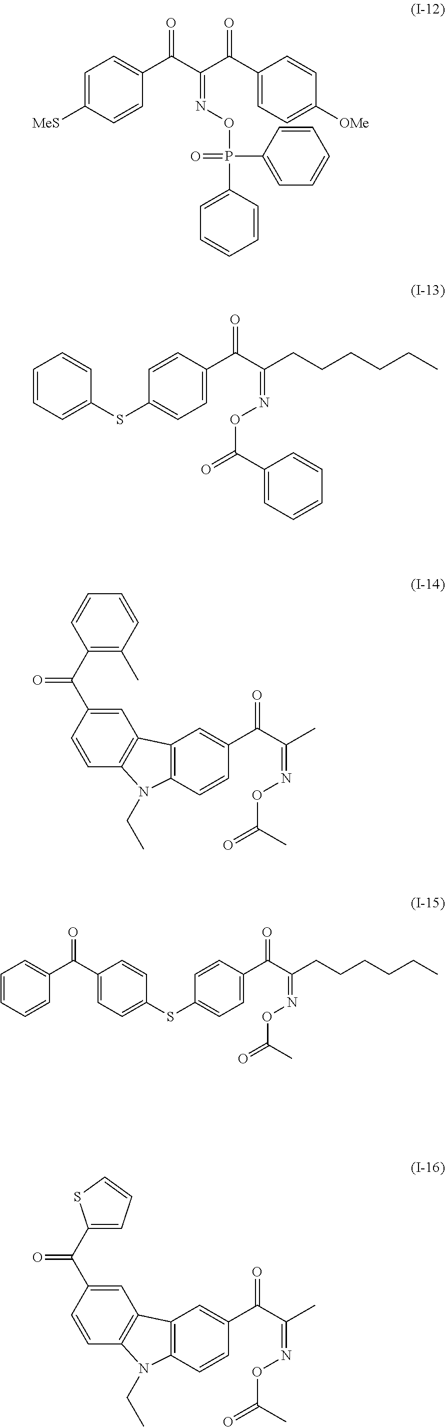

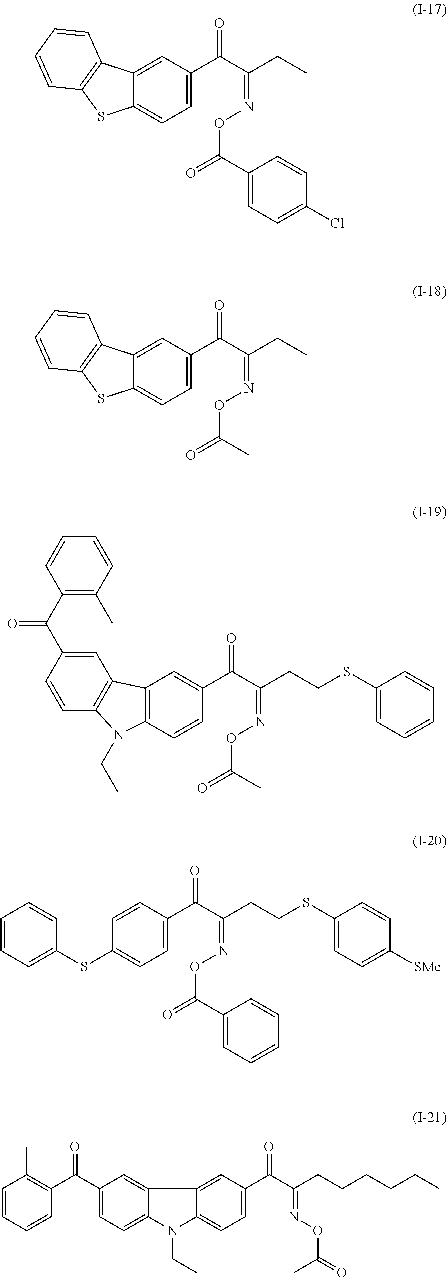

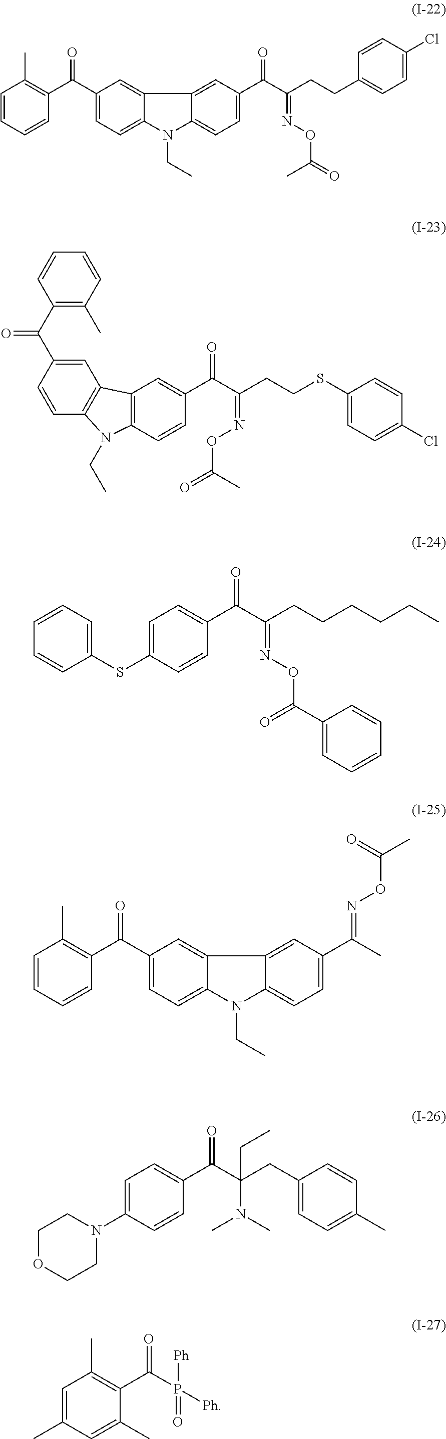

12. The black curable composition for a wafer-level lens according to claim 1, wherein the (C) polymerizable compound comprises at least one of pentaerythritol triacrylate or dipentaerythritol hexaacrylate.

13. The black curable composition for a wafer-level lens according to claim 1, further comprising (E) an organic pigment.

14. The black curable composition for a wafer-level lens according to claim 1 further comprising a pigment dispersant that includes a polyester-containing side chain and a side chain having a carboxylic acid group, a sulfonic acid group, or a phosphoric acid group.

15. A wafer-level lens comprising a substrate, a lens provided on the substrate, and a light-shielding film provided at a peripheral region of the lens, wherein the light-shielding film is formed using the black curable composition for a wafer-level lens of claim 1.

16. A method of forming a light-shielding pattern including:
forming a black curable layer containing the black curable composition for a wafer level lens of claim 1 on a substrate on which a plurality of lenses are provided; and
patternwise exposing the black curable layer to light and developing the black curable layer, thereby forming, at peripheral regions of the plurality of lenses, light-shielding portions containing a cured product of the black curable composition for a wafer level lens.
